(19) United States
(12) Patent Application Publication
(10) Pub. No.: US 2025/0226341 A1
(43) Pub. Date: Jul. 10, 2025

(54) BONDING STRUCTURE AND PACKAGE STRUCTURE

(71) Applicant: Advanced Semiconductor Engineering, Inc., Kaohsiung (TW)

(72) Inventors: Chien-Ching CHEN, Kaohsiung (TW); Man-Wen TSENG, Kaohsiung (TW); Yu-Sheng CHANG, Kaohsiung (TW); Chia-Cheng HUANG, Kaohsiung (TW)

(73) Assignee: Advanced Semiconductor Engineering, Inc., Kaohsiung (TW)

(21) Appl. No.: 18/406,021

(22) Filed: Jan. 5, 2024

(51) Int. Cl. H01L 23/00

(52) U.S. Cl. CPC H01L 24/08; H01L 24/05; H01L 2224/05557; H01L 2224/0807; H01L 2224/08145; H01L 2224/08221

(57) ABSTRACT

A bonding structure and a package structure are provided. The bonding structure includes a first pad and a wire bundle structure. The wire bundle structure is protruded from the first pad and tapering away from the first pad. The wire bundle structure includes a first portion and a second portion, the first portion is closer to the first pad than the second portion is, and in a cross-sectional view perspective, a width of a first void in the first portion is less than a width of a second void in the second portion.

### BACKGROUND

### 1. Technical Field

The present disclosure relates generally to a bonding structure and a package structure.

### 2. Description of the Related Art

Currently, copper pads may be bonded to each other through nanowires. However, the nanowires may bend toward various directions upon pressure during the bonding process, which is disadvantageous to electrical connection performance.

### SUMMARY

In one or more arrangements, a bonding structure includes a first pad and a wire bundle structure. The wire bundle structure is protruded from the first pad and tapering away from the first pad. The wire bundle structure includes a first portion and a second portion, the first portion is closer to the first pad than the second portion is, and in a cross-sectional view perspective, a width of a first void in the first portion is less than a width of a second void in the second portion.

In one or more arrangements, a bonding structure includes a first pad, a second pad, and a wire bundle structure. The second pad is over the first pad. The wire bundle structure connects the first pad to the second pad and at least partially tapers in a direction from the second pad toward the first pad. The wire bundle structure includes a first portion connected to the first pad and a second portion connected to the second pad, and an aspect ratio of a void in the second portion is greater than an aspect ratio of a void in the first portion.

In one or more arrangements, a package structure includes a first substrate, a second substrate, and a plurality of wires. The first substrate includes a guiding structure. The second substrate is over the first substrate. The wires are electrically connected to the first substrate and the second substrate and at least partially contacting the guiding structure, wherein the guiding structure is configured to reduce entanglement of the wires.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIG. 1A is a cross-section of a package structure in accordance with some arrangements of the present disclosure.

FIG. 1B is a cross-section of a package structure in accordance with some arrangements of the present disclosure.

FIG. 1C is a cross-section of a package structure in accordance with some arrangements of the present disclosure.

FIG. 1D is a top view of a package structure in accordance with some arrangements of the present disclosure.

FIG. 1E is a cross-section of a package structure in accordance with some arrangements of the present disclosure.

FIG. 1F is a cross-section of a package structure in accordance with some arrangements of the present disclosure.

FIG. 1G is a cross-section of a package structure in accordance with some arrangements of the present disclosure.

FIG. 1H is a cross-section of a package structure in accordance with some arrangements of the present disclosure.

FIG. 2A is a cross-section of a package structure in accordance with some arrangements of the present disclosure.

FIG. 2B is a cross-section of a package structure in accordance with some arrangements of the present disclosure.

FIG. 2C is a cross-section of a package structure in accordance with some arrangements of the present disclosure.

FIG. 2D is a top view of a package structure in accordance with some arrangements of the present disclosure.

FIG. 2E is a cross-section of a package structure in accordance with some arrangements of the present disclosure.

FIG. 3A is a cross-section of a package structure in accordance with some arrangements of the present disclosure.

FIG. 3B is a cross-section of a package structure in accordance with some arrangements of the present disclosure.

FIG. 4A, FIG. 4B, FIG. 4C, FIG. 4D, and FIG. 4E illustrate various stages of an exemplary method for manufacturing a package structure in accordance with some embodiments of the present disclosure.

FIG. 5A, FIG. 5B, FIG. 5C, FIG. 5D, and FIG. 5E illustrate various stages of an exemplary method for manufacturing a package structure in accordance with some embodiments of the present disclosure.

FIG. 6A, FIG. 6B, FIG. 6C, FIG. 6D, and FIG. 6E illustrate various stages of an exemplary method for manufacturing a package structure in accordance with some embodiments of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

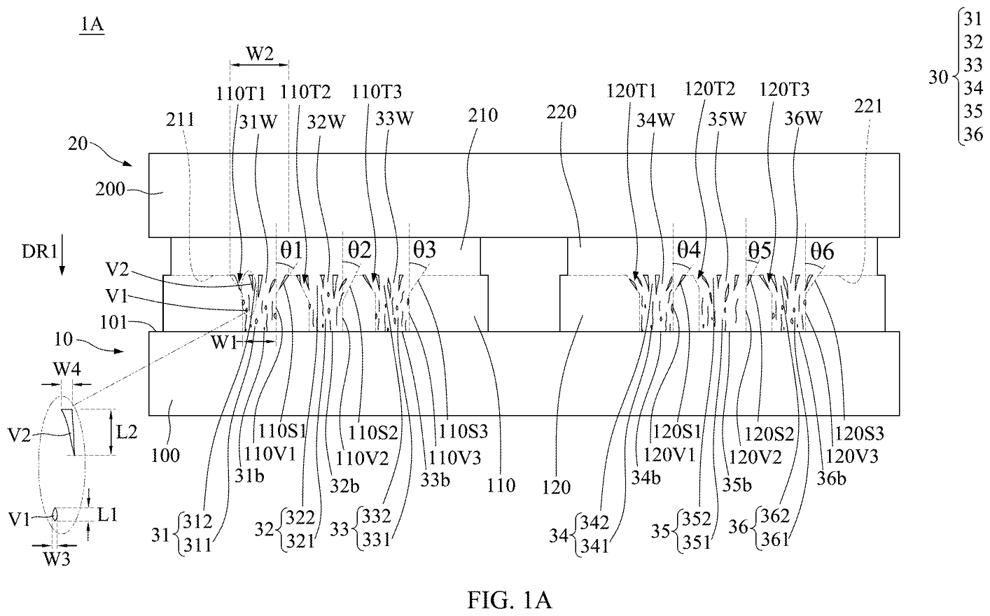

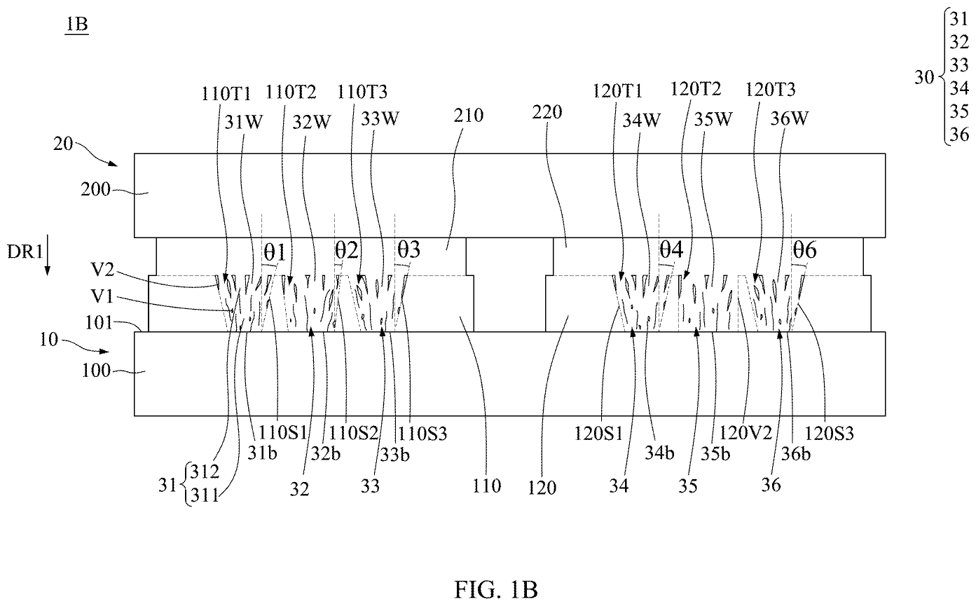

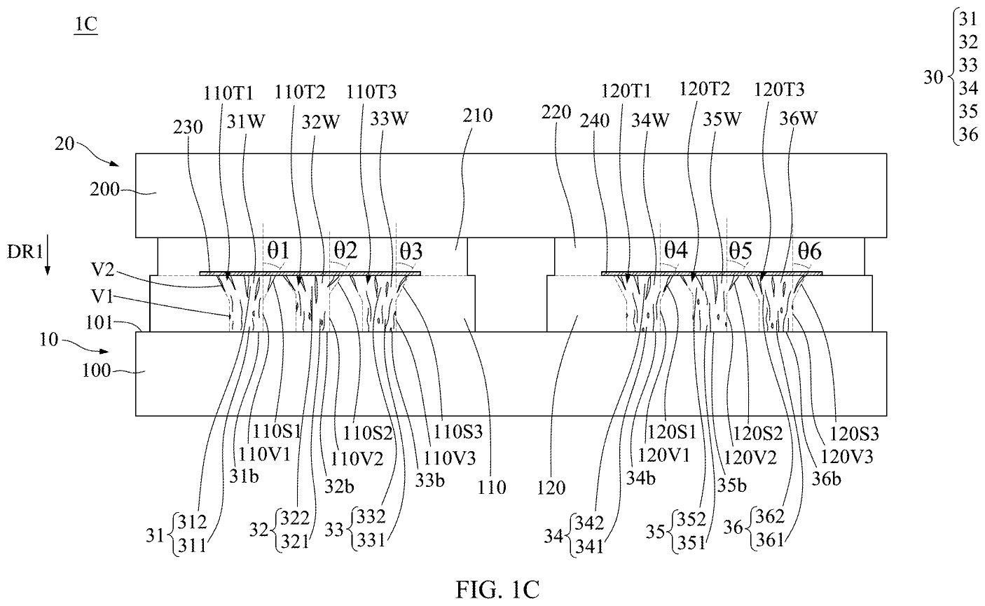

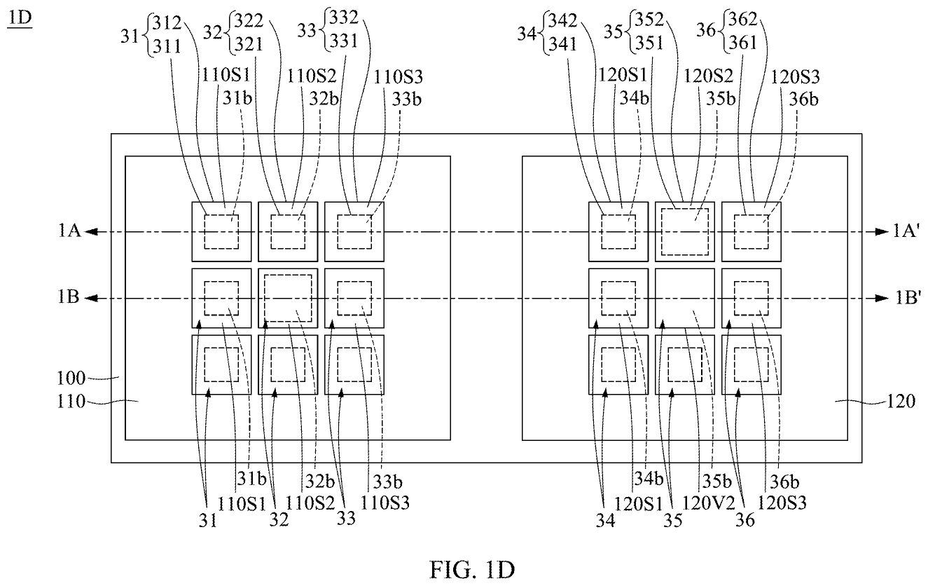

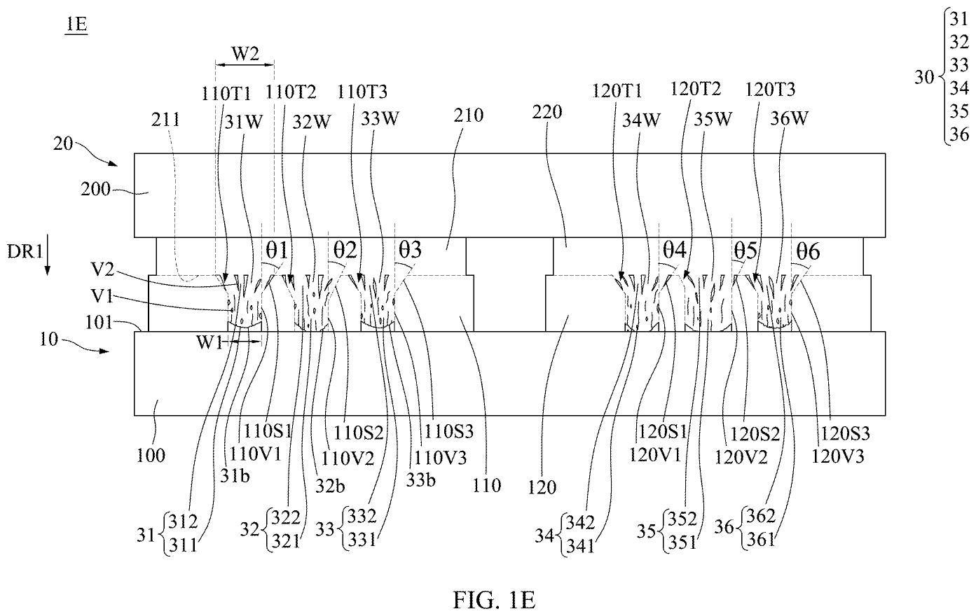

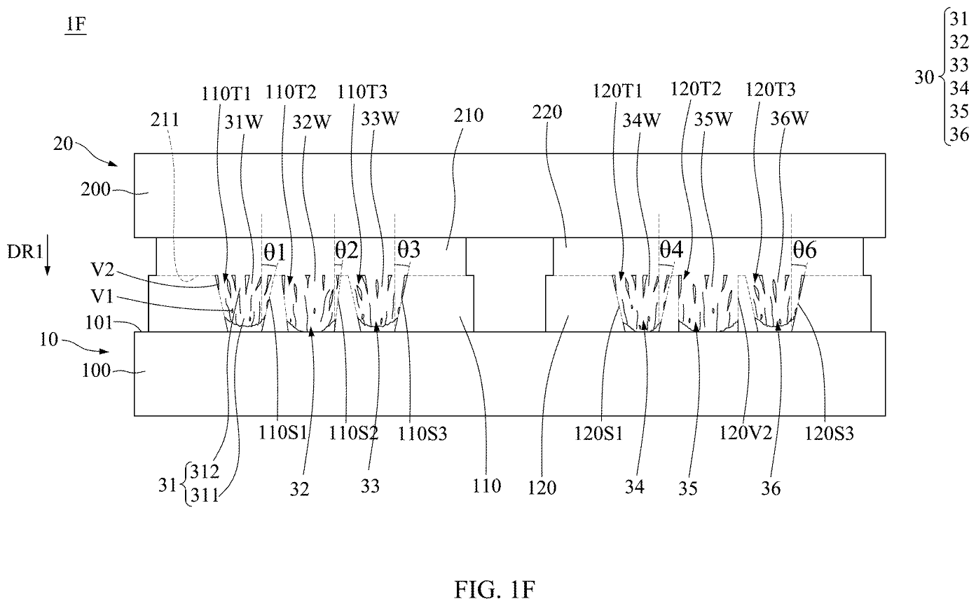

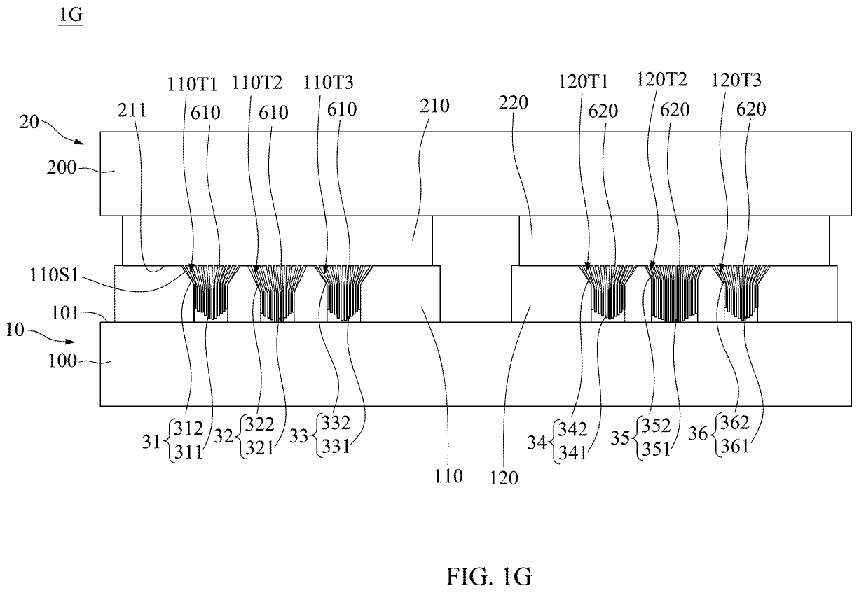

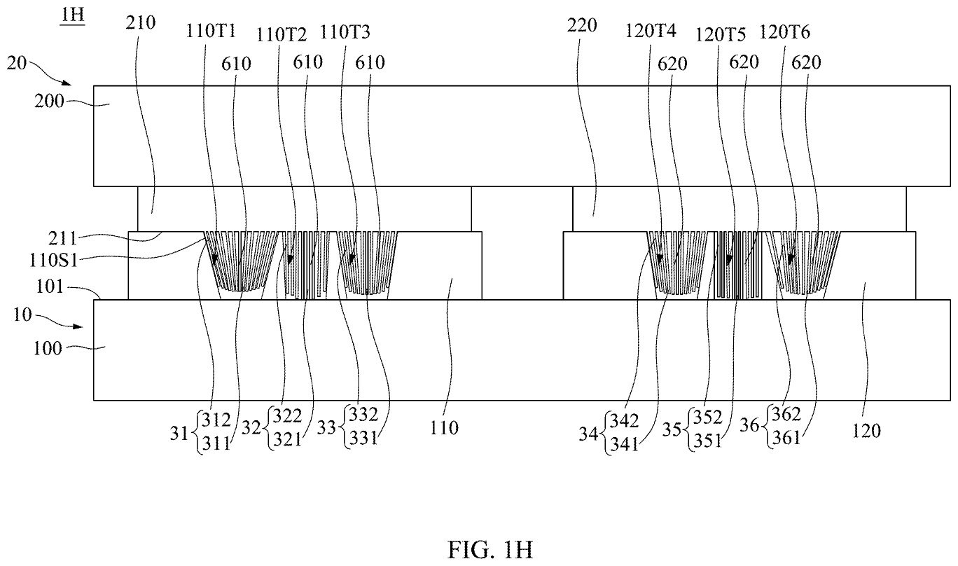

FIG. 1A is a cross-section of a package structure 1A in accordance with some arrangements of the present disclosure. The package structure 1A may include substrates 10 and 20 and a bundle structure 30.

The substrate 10 may include, for example, a printed circuit board, such as a paper-based copper foil laminate, a composite copper foil laminate, or a polymer-impregnated glass-fiber-based copper foil laminate. The substrate 10 may include an interconnection structure, which may include such as a plurality of conductive traces and/or a plurality of conductive vias. The interconnection structure may include a redistribution layer (RDL) and/or a grounding element. In some arrangements, the substrate 10 may include an organic substrate or a leadframe. In some arrangements, the substrate 10 includes a ceramic material or a metal plate. In some arrangements, the substrate 10 may include a two-layer substrate which includes a core layer and a conductive material and/or structure disposed on an upper surface and a bottom surface of the substrate 10. The substrate 10 may include a semiconductor wafer or an electronic component. The electronic component may be a chip or a die including a semiconductor substrate, one or more integrated circuit devices and one or more overlying interconnection structures therein. The integrated circuit devices may include active devices such as transistors and/or passive devices such resistors, capacitors, inductors, or a combination thereof. In some arrangements, the substrate 10 includes one or more conductive elements, surfaces, contacts, or pads. The substrate 10 may be referred to as a wiring structure, a circuit structure, a conductive structure, or a conductive carrier.

In some arrangements, the substrate 10 includes a base layer 100 and pads 110 and 120. The base layer 100 may be or include a semiconductor layer, a dielectric layer, or other suitable substrate layer. The pads 110 and 120 may be referred to as conductive pads or conductive layers. In some arrangements, the pads 110 and 120 are disposed or formed on a surface 101 of the base layer 100. In some arrangements, the pad 110 defines one or more trenches (e.g., trenches 110T1, 110T2, and 110T3). The trenches 110T1, 110T2, and 110T3 may be referred to as cavities, through holes, or recesses. In some arrangements, one or more of the trenches 110T1, 110T2, and 110T3 (or the cavities) may at least partially taper toward the base layer 100. In some arrangements, one or more of the trenches 110T1, 110T2, and 110T3 (or the cavities) may at least partially taper away from the substrate 20. In some arrangements, the pad 120 defines one or more trenches (e.g., trenches 120T1, 120T2, and 120T3). The trenches 120T1, 120T2, and 120T3 may be referred to as cavities, through holes, or recesses. In some arrangements, one or more of the trenches 120T1, 120T2, and 120T3 (or the cavities) may at least partially taper toward the base layer 100. In some arrangements, one or more of the trenches 120T1, 120T2, and 120T3 (or the cavities) may at least partially taper away from the substrate 20. The pads 110 and 120 may be or include a conductive material such as a metal or metal alloy, for example, gold (Au), silver (Ag), aluminum (Al), copper (Cu), or an alloy thereof. In some arrangements, the pads 110 and 120 are formed of or include Cu.

In some arrangements, each of the trenches 110T1, 110T2, 110T3, 120T1, 120T2, and 120T3 has one or more inclined sidewalls inclined with respect to the surface 101 of the base layer 100. In some arrangements, each of the trenches 110T1, 110T2, 110T3, 120T1, 120T2, and 120T3 further has one or more vertical sidewalls extending toward the base layer 100, and the one or more inclined sidewalls are inclined with respect to the corresponding vertical sidewalls. In some arrangements, the trench 110T1 has a vertical sidewall 110V1 and a sidewall 110S1 inclined with respect to the vertical sidewall 110V1. In some arrangements, the trench 110T2 has a vertical sidewall 110V2 and a sidewall 110S2 inclined with respect to the vertical sidewall 110V2. In some arrangements, the trench 110T3 has a vertical sidewall 110V3 and a sidewall 110S3 inclined with respect to the vertical sidewall 110V3. In some arrangements, the trench 120T1 has a vertical sidewall 120V1 and a sidewall 120S1 inclined with respect to the vertical sidewall 120V1. In some arrangements, the trench 120T2 has a vertical sidewall 120V2 and a sidewall 120S2 inclined with respect to the vertical sidewall 120V2. In some arrangements, the trench 120T3 has a vertical sidewall 120V3 and a sidewall 120S3 inclined with respect to the vertical sidewall 120V3. In some arrangements, at least two slopes of at least two sidewalls of the trenches 110T1, 110T2, 110T3, 120T1, 120T2, and 120T3 are different from each other. For example, a slope of the sidewall 110S1 of the trench 110T1 is different from a slope of the sidewall 110S2 of the trench 110T2. For example, a slope of the sidewall 120S1 of the trench 120T1 is different from a slope of the sidewall 120S2 of the trench 120T2.

The substrate 20 may be disposed over the substrate 10. The substrate 20 may be connected or electrically connected to the substrate 10. The substrate 20 may include, for example, a printed circuit board, such as a paper-based copper foil laminate, a composite copper foil laminate, or a polymer-impregnated glass-fiber-based copper foil laminate. The substrate 20 may include an interconnection structure, which may include a plurality of conductive traces and/or a plurality of conductive vias. The interconnection structure may include an RDL and/or a grounding element. In some arrangements, the substrate 20 may include such as an organic substrate or a leadframe. In some arrangements, the substrate 20 includes a ceramic material or a metal plate. In some arrangements, the substrate 20 may include a two-layer substrate which includes a core layer and a conductive material and/or structure disposed on an upper surface and a bottom surface of the substrate 20. The substrate 20 may include a semiconductor wafer or an electronic component. The electronic component may be a chip or a die including a semiconductor substrate, one or more integrated circuit devices and one or more overlying interconnection structures therein. The integrated circuit devices may include active devices such as transistors and/or passive devices such resistors, capacitors, inductors, or a combination thereof. In some arrangements, the substrate 20 includes one or more conductive elements, surfaces, contacts, or pads. The substrate 20 may be or include an electronic module including one or more electronic components. The electronic components may be active components, passive components, or other suitable components, for example, one or more processing components (e.g., ASIC), one or more memory components (e.g., HBM), or a combination thereof.

The substrate 20 may be disposed over the substrate 10. In some arrangements, the substrate 20 includes abase layer 200 and pads 210 and 220. The base layer 200 may be or include a semiconductor layer, a dielectric layer, or other suitable substrate layer. The pads 210 and 220 may be referred to as conductive pads or conductive layers. In some arrangements, the pad 210 is over the pad 110. In some arrangements, the pad 210 contacts the pad 110. In some arrangements, the pad 220 is over the pad 120. In some arrangements, the pad 220 contacts the pad 120. The pads 210 and 220 may be or include a conductive material such as a metal or metal alloy, for example, gold (Au), silver (Ag), aluminum (Al), copper (Cu), or an alloy thereof. In some arrangements, the pads 210 and 220 are formed of or include Cu.

The bundle structure 30 may electrically connect the substrate 20 to the substrate 10. In some arrangements, the bundle structure 30 includes a plurality of wires (e.g., wires 31W, 32W, 33W, 34W, 35W, and 36W). In some arrangements, the wires 31W, 32W, and 33W are formed from a surface 211 (also referred to as “a lower surface” or “a bottom surface”) of the pad 210. In some arrangements, the pad 210 serves as a substrate or a base pad for forming or growing the wires. In some arrangements, the wires 31W, 32W, and 33W are protruded from or out of the surface 211 of the pad 210. In some arrangements, the wires 31W, 32W, and 33W are nanowires (e.g., conductive nanowires). In some arrangements, the wires 34W, 35W, and 36W are formed from a surface 221 (also referred to as “a lower surface” or “a bottom surface”) of the pad 220. In some arrangements, the pad 220 serves as a substrate or a base pad for forming or growing the wires. In some arrangements, the wires 34W, 35W, and 36W are protruded from or out of the surface 221 of the pad 220. In some arrangements, the wires 34W, 35W, and 36W are nanowires (e.g., conductive nanowires). In some arrangements, the sidewall 110S1 is inclined with respect to the surface 211 of the pad 210. In some arrangements, the sidewall 110S1 is configured to guide the wires of the wire bundle structure 31 to gather toward a direction away from the pad 210. In some arrangements, the sidewall 110S1 is configured to gradually reduce a horizontal distance between the wires of the wire bundle structure 31. In some arrangements, the sidewall 110S1 is configured to increase a contact area between the wires of the wire bundle structure 31. In some arrangements, the bundle structure 30 includes a plurality of wire bundle structures (e.g., wire bundle structures 31, 32, 33, 34, 35, and 36). The wire bundle structures may be referred to as wire bundles. Each of the wire bundle structures (or the wire bundles) includes a plurality of wires (e.g., conductive wires or conductive nanowires). The wire bundle structures 31, 32, 33, 34, 35, and 36 may be or include a conductive material such as a metal or metal alloy, for example, gold (Au), silver (Ag), aluminum (Al), copper (Cu), or an alloy thereof. In some arrangements, the wire bundle structures 31, 32, 33, 34, 35, and 36 are formed of or include Cu.

In some arrangements, the wire bundle structure 31 connects the pad 110 to the pad 210. In some arrangements, the wire bundle structure 31 is protruded from the pad 210 and tapers away from the pad 210. In some arrangements, the wire bundle structure 31 at least partially tapers in a direction DR1 from the pad 210 toward the pad 110. In some arrangements, the trench 110T1 (or the recess) of the pad 110 accommodates the wire bundle structure 31. In some arrangements, in the cross-sectional view perspective, the trench 110T1 has two lateral sidewalls (e.g., the sidewalls 110S1) opposite to each other, and a distance between the two lateral sidewalls increases toward the pad 210. For example, the width W2 is greater than the width W1. In some arrangements, a cross-sectional profile of the wire bundle structure 31 is substantially conformal with a cross-sectional shape of the trench 110T1. In some arrangements, the wire bundle structure 31 and the pad 110 are formed of or include the same metal material. In some arrangements, the wire bundle structure 31 is at least partially formed integrally with the pad 110 without a heterogeneous interface formed therebetween. In some arrangements, the wire bundle structure 31 and the pad 210 are formed of or include the same metal material. In some arrangements, the wire bundle structure 31 is at least partially formed integrally with the pad 210 without a heterogeneous interface formed therebetween. In some arrangements, the wire bundle structure 31 includes portions 311 and 312.

In some arrangements, the portion 311 (also referred to as “lower portion” or “vertical portion”) is connected to the pad 110. In some arrangements, the portion 311 directly contacts the pad 110. In some arrangements, the portion 311 directly contacts the sidewall 110V1 of the trench 110T1 of the pad 110. In some arrangements, the portion 311 is partially formed integrally with the pad 110 without a heterogeneous interface formed therebetween. In some arrangements, the portion 311 has a substantially constant width. In some arrangements, the portion 311 has substantially vertical sidewalls (e.g., the sidewalls 110V1). In some arrangements, voids V1 are formed in the portion 311. In some arrangements, the portion 311 has voids V1. In some arrangements, the wire bundle structure 31 (or the portion 311) is partially spaced apart from the sidewall 110V1 of the trench 110T1 by at least one of the voids V1 in the portion 311 of the wire bundle structure 31.

In some arrangements, the portion 312 (also referred to as “upper portion” or “tapered portion”) is connected to the portion 311. In some arrangements, the portion 312 tapers toward the portion 311. In some arrangements, the portion 312 directly contacts the portion 311. In some arrangements, the portion 312 is at least partially formed integrally with the portion 311. In some arrangements, the portion 311 and the portion 312 integrally form a monolithic wire bundle structure 31 (or a single-piece wire bundle structure 31). In some arrangements, the portion 312 is at least partially formed integrally with the pad 210. In some arrangements, voids V2 are formed in the portion 312. In some arrangements, the portion 312 has voids V2. In some arrangements, the wire bundle structure 31 (or the portion 312) is partially spaced apart from the sidewall 110S1 of the trench 110T1 by at least one of the voids V2 in the portion 312 of the wire bundle structure 31. In some arrangements, the voids V2 in the portion 312 may extend in a direction (e.g., the direction DR1) toward the portion 311. In some arrangements, the voids V2 in the portion 312 may extend in a direction (e.g., the direction DR1) extending between the pad 210 and the portion 311.

In some arrangements, the portion 311 is closer to the pad 210 than the portion 312 is. In some arrangements, a width W2 of the portion 312 is greater than a width W1 of the portion 311 in a cross-sectional view perspective. In some arrangements, the width W2 of the portion 312 decreases toward the portion 311. In some arrangements, a height of the portion 311 is equal to or greater than a height of the portion 312. In some arrangements, a ratio of the height of the portion 312 to a total height of the wire bundle structure 31 is from about 0.3 to about 0.5.

In some arrangements, a number of the voids V2 in the portion 312 is greater than a number of the voids V1 in the portion 311. In some arrangements, a distribution density of the voids V2 in the portion 312 is greater than a distribution density of the voids V1 in the portion 311. In some arrangements, the void V2 extends in a direction non-parallel to the surface 211 of the pad 210. In some arrangements, lateral surfaces of the wires of the wire bundle structure 31 are connected to each other, and the voids V2 are formed between portions of the lateral surfaces of the wires that are not connected to each other. In some arrangements, the void V2 has a strip shape in a cross-sectional view perspective. In some arrangements, a length L2 of the void V2 in the portion 312 is greater than a length L1 of the void V1 in the portion 311. In some arrangements, a width W4 of the void V2 in the portion 312 is greater than a width W3 of the void V1 in the portion 311. In some arrangements, the width W4 of the void V2 increases toward the pad 210. In some arrangements, an aspect ratio L2/W4 of the void V2 in the portion 312 is greater than an aspect ratio L1/W3 of the void V1 in the portion 311. The length of the voids may refer to the size or the dimension measured in a direction toward the portion 311 or in a direction extending between the pad 210 and the portion 311 (e.g., the direction DR1). In some arrangements, the length of the void V2 refers to the size or dimension of a long axis of the void V2, and the width of the void V2 refers to a short axis of the void V2.

In some arrangements, the wire bundle structure 32 includes portions 321 and 322, the wire bundle structure 33 includes portions 331 and 332, the wire bundle structure 34 includes portions 341 and 342, the wire bundle structure 35 includes portions 351 and 352, and the wire bundle structure 36 includes portions 361 and 362. In some arrangements, the wire bundle structure 31, 32, and 33 electrically connect the pad 110 to the pad 210. In some arrangements, bottom surfaces 31b, 32b, and 33b of the wire bundle structure 31, 32, and 33 contact the pad 110. In some arrangements, the wire bundle structure 34, 35, and 36 electrically connect the pad 120 to the pad 220. In some arrangements, bottom surfaces 34b, 35b, and 36b of the wire bundle structure 34, 35, and 36 contact the pad 120. In some arrangements, each of the wire bundle structures 32, 33, 34, 35, and 36 may have a structure similar to that of the wire bundle structure 31, and the descriptions thereof are omitted here.

In some arrangements, at least two of the vertical portions (e.g., the portions 311, 321, 331, 341, 351, and 361) of the wire bundle structures 31, 32, 33, 34, 35, and 36 may have different heights. In some arrangements, a height of the portion 321 is less than heights of the portion 311 and 331. In some arrangements, a height of the portion 351 is greater than heights of the portion 341 and 361. In some arrangements, at least two of the vertical portions of the wire bundle structures 31, 32, 33, 34, 35, and 36 may have different widths. In some arrangements, a width of the portion 351 is greater than widths of the portions 341 and 361. In some arrangements, at least two of the tapered portions (e.g., the portions 312, 322, 332, 342, 352, and 362) of the wire bundle structures 31, 32, 33, 34, 35, and 36 may have different heights. In some arrangements, a height of the portion 322 is greater than heights of the portion 312 and 332. In some arrangements, a height of the portion 352 is less than heights of the portion 342 and 362. In some arrangements, at least two of the tapered portions of the wire bundle structures 31, 32, 33, 34, 35, and 36 may have different widths. In some arrangements, at least two of the tapered portions of the wire bundle structures 31, 32, 33, 34, 35, and 36 may have sidewalls (e.g., the sidewalls 110S1, 110S2, 110S3, 120S1, 120S2, and 120S3) or lateral surfaces with different inclined angles (e.g., angles θ1, θ2, θ3, θ4, θ5, and θ6). The inclined angle may be defined by an extending line of a vertical sidewall (e.g., the sidewalls 110V1, 110V2, 110V3, 120V1, 120V2, and 120V3) of the vertical portion and the sidewall (e.g., the sidewalls 110S1, 110S2, 110S3, 120S1, 120S2, and 120S3) of the tapered portion. In some arrangements, the angle θ1 is substantially equal to the angle θ3. In some arrangements, the angle θ1 is greater than the angle θ2. In some arrangements, the angle θ4 is substantially equal to the angle θ6. In some arrangements, the angle θ5 is greater than the angle θ4.

In some arrangements, the wire bundle structure 31 includes a plurality of wires 31W, the wire bundle structure 32 includes a plurality of wires 32W, the wire bundle structure 33 includes a plurality of wires 33W, the wire bundle structure 34 includes a plurality of wires 34W, the wire bundle structure 35 includes a plurality of wires 35W, and the wire bundle structure 36 includes a plurality of wires 36W. In some arrangements, the wires 31W, 32W, 33W, 34W, 35W, and 36W are electrically connected to the substrate 10 and the substrate 20.

In some arrangements, the pads 110 and 120 may be referred to as or include one or more guiding structures. The guiding structure (e.g., the pad 110 and/or the pad 120) may define a plurality of trenches tapering toward the base layer 100. The trenches of the guiding structure (e.g., the pad 110 and/or the pad 120) may taper away from the substrate 20. In some arrangements, the wires 31W, 32W, and 33W at least partially contact the pad 110 (or the guiding structure). In some arrangements, the guiding structure (or the pad 110) is configured to reduce entanglement of the wires 31W, 32W, and 33W. In some arrangements, the wires 34W, 35W, and 36W at least partially contact the pad 120 (or the guiding structure). In some arrangements, the guiding structure (or the pad 120) is configured to reduce entanglement of the wires 34W, 35W, and 36W.

In some arrangements, the guiding structure defines a plurality of guiding slopes (or slopes) configured for directing the wires to extend from the substrate 20 toward the substrate 10 along the guiding slopes. For example, the sidewall 110S1 defined by the pad 110 may serve as a guiding slope that is configured for directing the wires 31W to extend from the pad 210 of the substrate 20 toward the substrate 10 along the sidewall 110S1. In some arrangements, an angle θ1 defined by the slope or the guiding slope (e.g., the sidewall 110S1) and a normal line of a surface 101 of the substrate 10 is from about 15° to about 45°. In some arrangements, the plurality of guiding slopes may include a first slope (e.g., the sidewall 110S1) adjacent to an edge of the guiding structure and a second slope (e.g., the sidewall 110S2) distal from the edge of the guiding structure. In some arrangements, an angle θ2 defined by the second slope (e.g., the sidewall 110S2) and the normal line of the surface 101 of the substrate 10 may be substantially the same as or different from the angle θ1. In some arrangements, the angle θ1 is from about 15° to about 45° and greater than the angle θ2, such that the wires 31W may be directed to extend downward to the surface 101 of the substrate 10 without bending outwards and protruding the edge of the pad 110.

In some arrangements, the guiding structure further defines a plurality of vertical sidewalls each connected to each of the guiding slopes and configured for further directing the wires to extend toward the substrate 10 along the vertical sidewalls. For example, the vertical sidewall 110V1 is connected to the sidewall 110S1 and configured for further directing the wires 31W to extend toward the substrate 10 along the vertical sidewall 110V1. In some arrangements, at least two vertical sidewalls of the plurality of vertical sidewalls have different heights. For example, the vertical sidewalls 110V1 and 110V2 have different heights. For example, the vertical sidewalls 120V1 and 120V2 have different heights.

In some arrangements, the guiding structure includes trenches having tapered structures or tapered cross-sectional profiles that are defined by the guiding slopes and the vertical sidewalls. For example, the tapered structure of the trench 110T1 is defined by the sidewall 110S1 and the vertical sidewall 110V1. In some arrangements, the wires 31W are disposed in the trench 110T1, and a spacing between the wires 31W decreases toward the substrate 10. In some arrangements, the wires 32W are disposed in the trench 110T2, and a spacing between the wires 32W decreases toward the substrate 10. In some arrangements, the wires 33W are disposed in the trench 110T3, and a spacing between the wires 33W decreases toward the substrate 10. In some arrangements, the wires 34W are disposed in the trench 120T1, and a spacing between the wires 34W decreases toward the substrate 10. In some arrangements, the wires 35W are disposed in the trench 120T2, and a spacing between the wires 35W decreases toward the substrate 10. In some arrangements, the wires 36W are disposed in the trench 120T3, and a spacing between the wires 36W decreases toward the substrate 10. For example, some portions of the wires 31W (e.g., upper portions of the wires 31W in the portion 312) may be partially spaced apart from each other by the relatively large voids V2, such that the spacing between the wires 31W in the portion 312 may be relatively large. In addition, for example, some portions of the wires 31W (e.g., lower portions of the wires 31W in the portion 311) may be forced or pushed to be close to each other by the narrow lower portion of the trench 110T1 and thus are partially spaced apart from each other by the relatively small voids V1, such that the spacing between the wires 31W in the portion 311 may be relatively small. Similar situation may be applied to the wires 32W, 33W, 34W, 35W, and 36W.

In some arrangements, the guiding structure is or includes a conductive layer (e.g., the pad 110), and a portion of the wires 31W are disposed in the trench 110T1 (or the cavity) and formed integrally with the guiding structure (or the pad 110). In some arrangements, a portion of the wires 32W are disposed in the trench 110T2 (or the cavity) and formed integrally with the guiding structure (or the pad 110). In some arrangements, a portion of the wires 33W are disposed in the trench 110T3 (or the cavity) and formed integrally with the guiding structure (or the pad 110). In some arrangements, a portion of the wires 34W are disposed in the trench 120T1 (or the cavity) and formed integrally with the guiding structure (or the pad 120). In some arrangements, a portion of the wires 35W are disposed in the trench 120T2 (or the cavity) and formed integrally with the guiding structure (or the pad 120). In some arrangements, a portion of the wires 36W are disposed in the trench 120T3 (or the cavity) and formed integrally with the guiding structure (or the pad 120).

In some arrangements, the pad 110, the pad 210, and the wire bundle structure 31 may collectively form a bonding structure for bonding the substrate 10 to the substrate 20. In some arrangements, the pad 110, the pad 210, and the wire bundle structures 31, 32, and 33 may collectively form a bonding structure for bonding the substrate 10 to the substrate 20. In some arrangements, the pad 120, the pad 220, and the wire bundle structures 34, 35, and 36 may collectively form a bonding structure for bonding the substrate 10 to the substrate 20. In some arrangements, the pads 110 and 120, the pads 210 and 220, and the wire bundle structures 31, 32, 33, 34, 35, and 36 may collectively form a bonding structure for bonding the substrate 10 to the substrate 20.

In some cases where copper pads may be bonded to each other through nanowires, the nanowires may bend toward various random directions during the bonding process. The nanowires may form bent structures which undesirably increase conductive paths. In addition, some of the nanowires may further bend toward directions away from the copper pads and protrude the edges of the copper pads. As such, the nanowires that bent outwards and protruding the edges of the copper pads fail to provide conductive paths between the copper pads, and the bent structures of the nanowires between the copper pads undesirably increase the conductive paths between the copper pads. The above situations increase the resistance of the conductive paths between the copper pads and thus are disadvantageous to the electrical connection performance.

According to some arrangements of the present disclosure, the wires may be directed to extend between pads of opposing substrates by the guiding structure without bending outwards and protruding the edges of the pads. Therefore, the formation of bent structures of the wires can be reduced, the number of the wires that protrude the edges of the pads can be reduced as well, thus the conductive paths between the pads of opposing substrates can be reduced, and the electrical connection performance between the pads of opposing substrates can be improved.

In addition, according to some arrangements of the present disclosure, the guiding structure defines trenches including guiding slopes configured for directing the wires to extend from the one substrate toward another substrate along the guiding slopes. As the wires encounter the guiding slopes during the bonding process, the wires will naturally extend into the trenches along the extending directions of the guiding slopes, such that the wires can naturally be arranged neatly and extend between the pads of opposing substrates. Therefore, the formation of bent structures of the wires can be further reduced, the wires can be further prevented from protruding the edges of the pads, thus the conductive paths between the pads of opposing substrates can be reduced, and the electrical connection performance between the pads of opposing substrates can be further improved.

Furthermore, according to some arrangements of the present disclosure, the lengths of the wires can be reduced since formation of bent structures is reduced, wires with reduced lengths are still long enough to extend between the pads of opposing substrates. Accordingly, the wires with reduced lengths can provided further improved electrical connection performance. In addition, with the reduced lengths of the wires, the distances originally reserved for some of the wires to accidentally protrude between the trenches and edges of the pads can also be reduced. Accordingly, the size of the package structure can be reduced.

Moreover, according to some arrangements of the present disclosure, the trenches of the guiding structure include relatively wide upper portions and relatively narrow lower portions. After the wires are introduced into the trenches along the guiding slopes and entering the narrow lower portions of the trenches, the wires in the narrow lower portions may be further straightened and densely confined within the space of the narrow lower portions of the trenches. Thus, the wires not only can be arranged neatly but also can be arranged very close to each other. Therefore, after the wires are sintered and melted to form the wire bundle structures, very few voids may be formed in the lower portions of the wire bundle structures, and thus increase of resistance due to voids can be prevented effectively.

In addition, according to some arrangements of the present disclosure, with the wires being straightened and densely confined within the trenches are arranged very closely to each other, the sintering temperature of the wires can be further reduced accordingly.

Moreover, according to some arrangements of the present disclosure, the inclined angles of the guiding slopes are from about 15° to about 45°. The inclined angle being equal to or greater than about 15°, such that the angle can allow wires to be directed toward inside the trenches along the guiding slopes. The inclined angle being equal to or less than about 45°, such that the guiding slopes are not too steep to be too close to vertical sidewalls that may be effectively prevent the wires from protruding outwards the edges of the pads.

FIG. 1B is a cross-section of a package structure 1B in accordance with some arrangements of the present disclosure. The structure illustrated in FIG. 1B is similar to that in FIG. 1A, and the differences therebetween are described as follows.

In some arrangements, one or more of the lower portions of the wire bundle structures may further taper away from the upper portions of the wire bundle structures. For example, the portion 311 tapers away from the portion 312. In some arrangements, the portion 311 is or includes a tapered portion and has a width decreasing away from the portion 312. In some arrangements, the portions 311 and 312 collectively form a tapered structure tapering from the pad 210 toward the surface 101 of the substrate 10. In some arrangements, the wire bundle structure 31 includes a tapered structure having a sidewall (e.g., the sidewall 110S1) extending between the pad 210 and the surface 101 of the substrate 10.

In some arrangements, the wire bundle structures 32, 33, 34, and 36 include tapered structures similar to that of the wire bundle structure 31. In some arrangements, two or more sidewalls (e.g. the sidewalls 110S1, 110S2, 110S3, 120S1, and 120S3) of the wire bundle structures 31, 32, 33, 34, and 36 may have different inclined angles (e.g., angles θ1, θ2, θ3, θ4, and θ6). In some arrangements, the angle θ1 is substantially equal to the angle θ3. In some arrangements, the angle θ1 is greater than the angle θ2. In some arrangements, the angle θ4 is substantially equal to the angle θ6.

In some arrangements, the wire bundle structure 35 includes a columnar structure having a substantially vertical sidewall (e.g. the vertical sidewall 120V2).

FIG. 1C is a cross-section of a package structure 1C in accordance with some arrangements of the present disclosure. The structure illustrated in FIG. 1C is similar to that in FIG. 1A, and the differences therebetween are described as follows.

In some arrangements, the package structure 2B further includes one or more seed layers (e.g., seed layers 230 and 240). In some arrangements, the seed layer 230 is between the pad 210 and the wire bundle structures 31 32, and 33. In some arrangements, the seed layer 230 directly contacts the pad 210. In some arrangements, the seed layer 230 directly contacts the wire bundle structures 31 32, and 33. In some arrangements, the seed layer 230 further directly contacts the pad 110. In some arrangements, the seed layer 240 is between the pad 220 and the wire bundle structures 34 35, and 36. In some arrangements, the seed layer 240 directly contacts the pad 220. In some arrangements, the seed layer 240 directly contacts the wire bundle structures 34 35, and 36. In some arrangements, the seed layer 240 further directly contacts the pad 120.

In some arrangements, a portion of the seed layer 230 is exposed to at least one void V2 in the upper portion (e.g., the portions 312, 322, and 332) of the wire bundle structure (e.g., the wire bundle structures 31, 32, and 33). In some arrangements, a portion of the pad 110 (e.g., the sidewall 110S1 of the pad 110) is exposed to at least one void V2 in the upper portion (e.g., the portions 312, 322, and 332) of the wire bundle structure (e.g., the wire bundle structures 31, 32, and 33). In some arrangements, a portion of the seed layer 240 is exposed to at least one void V2 in the upper portion (e.g., the portions 342, 352, and 362) of the wire bundle structure (e.g., the wire bundle structures 34, 35, and 36). In some arrangements, a portion of the pad 120 (e.g., the sidewall 120S2 of the pad 120) is exposed to at least one void V2 in the upper portion (e.g., the portions 342, 352, and 362) of the wire bundle structure (e.g., the wire bundle structures 34, 35, and 36). The seed layers 230 and 240 may be or include titanium (Ti), Cu, nickel (Ni), another metal, or an alloy (such as a titanium-tungsten alloy (TiW)).

FIG. 1D is a top view of a package structure 1D in accordance with some arrangements of the present disclosure. In some arrangements, FIG. 1D shows a top view of a portion of the package structure 1A illustrated in FIG. 1A. In some arrangements, FIG. 1A shows a cross-section along a line 1A-1A′ in FIG. 1D. In some arrangements, FIG. 1D shows a top view of a portion of the package structure 1B illustrated in FIG. 1B. In some arrangements, FIG. 1B shows a cross-section along a line 1B-1B′ in FIG. 1D. In some arrangements, FIG. 1D shows a top view of a portion of the package structure 1C illustrated in FIG. 1C. It should be noted that some elements (e.g., the substrate 20 and the pads 210 and 220) are omitted in FIG. 1D for clarity.

In some arrangements, a plurality of wire bundle structures (e.g., the wire bundle structure 31, 32, and 33) are connected to the pad 110, and a plurality of wire bundle structures (e.g., the wire bundle structure 34, 35, and 36) are connected to the pad 120.

In some arrangements, referring to FIG. 1A and FIG. 1D, the inclined angles (e.g., the angles θ4 and θ6) of the guiding slopes of the guiding structure in the edge portion of the pad 120 are greater than the inclined angle (e.g., the angle θ5) of the guiding slope of the guiding structure in the middle portion of the pad 120. In some arrangements, the inclined angles (e.g., the angles θ1 and θ3) of the guiding slopes of the guiding structure in the edge portion of the pad 110 are greater than the inclined angle (e.g., the angle θ2) of the guiding slope of the guiding structure in the middle portion of the pad 110. In some arrangements, an area of the bottom surface (e.g., the bottom surfaces 32b and 35b) of the vertical portion of the wire bundle structure (e.g., the wire bundle structures 32 and 35) in the middle portion of the pad 110 and/or the pad 120 is greater than an area of the bottom surface (e.g., the bottom surfaces 31b, 33b, 34b, and 36b) of the vertical portions of the wire bundle structures (e.g., the wire bundle structures 31, 33, 34, and 36) in the edge portion of the pad 110 and/or the pad 120.

According to some arrangements of the present disclosure, the inclined angles of the guiding slopes of the guiding structure in the edge portion of the pad are greater than the inclined angle of the guiding slope of the guiding structure in the middle portion of the pad. Since the wires in the middle portion of the pad are less likely to protrude outwards the edges of the pad, the wires may only extend between edges of the trenches. Therefore, with the inclined angles of the guiding slopes of the guiding structure in the middle portion of the pad being reduced, the area or the space of the trenches of the guiding structure in the middle portion of the pad can be increased (e.g., the area of the bottom surface 32b), and thus more wires can be disposed in the trench to increase the electrical conduction.

FIG. 1E is a cross-section of a package structure 1E in accordance with some arrangements of the present disclosure. The structure illustrated in FIG. 1E is similar to that in FIG. 1A, and the differences therebetween are described as follows.

In some arrangements, the wire bundle structure 31 has a lower surface (e.g., the surface 31b) that is at least partially spaced apart from a bottom surface of the trench 110T1. In some arrangements, the surface 31b of the wire bundle structure 31 is spaced apart from the bottom surface of the trench 110T1. In some arrangements, the surface 31b of the wire bundle structure 31 is concave toward the bottom surface of the trench 110T1. In some arrangements, the surface 31b of the wire bundle structure 31 has a non-planar surface. In some arrangements, the surface 31b of the wire bundle structure 31 has an irregular surface structure. In some arrangements, the surface 31b of the wire bundle structure 31 has a non-uniform surface structure.

In some arrangements, the wire bundle structure 32 has a lower surface (e.g., the surface 32b) that is at least partially spaced apart from a bottom surface of the trench 110T2. In some arrangements, the surface 32b of the wire bundle structure 32 is concave toward the bottom surface of the trench 110T2. In some arrangements, the surface 32b of the wire bundle structure 32 has a non-planar surface. In some arrangements, the surface 32b of the wire bundle structure 32 has an irregular surface structure. In some arrangements, the surface 32b of the wire bundle structure 32 has a non-uniform surface structure.

FIG. 1F is a cross-section of a package structure 1F in accordance with some arrangements of the present disclosure. The structure illustrated in FIG. 1F is similar to that in FIG. 1B, and the differences therebetween are described as follows.

In some arrangements, the wire bundle structure 31 has a lower surface (e.g., the surface 31b) that is at least partially spaced apart from a bottom surface of the trench 110T1. In some arrangements, the surface 31b of the wire bundle structure 31 is spaced apart from the bottom surface of the trench 110T1. In some arrangements, the surface 31b of the wire bundle structure 31 is concave toward the bottom surface of the trench 110T1. In some arrangements, the surface 31b of the wire bundle structure 31 has a non-planar surface. In some arrangements, the surface 31b of the wire bundle structure 31 has an irregular surface structure. In some arrangements, the surface 31b of the wire bundle structure 31 has a non-uniform surface structure.

In some arrangements, the wire bundle structure 32 has a lower surface (e.g., the surface 32b) that is at least partially spaced apart from a bottom surface of the trench 110T2. In some arrangements, the surface 32b of the wire bundle structure 32 is concave toward the bottom surface of the trench 110T2. In some arrangements, the surface 32b of the wire bundle structure 32 has a non-planar surface. In some arrangements, the surface 32b of the wire bundle structure 32 has an irregular surface structure. In some arrangements, the surface 32b of the wire bundle structure 32 has a non-uniform surface structure.

FIG. 1G is a cross-section of a package structure 1G in accordance with some arrangements of the present disclosure. The structure illustrated in FIG. 1G is similar to that in FIG. 1A, and the differences therebetween are described as follows.

In some arrangements, the sidewalls 110S1 are inclined with respect to the surface 211 of the pad 210. In some arrangements, the sidewall 110S1 is configured to guide the wires 610 of the wire bundle structure 31 to gather toward a direction away from the pad 210. In some arrangements, the sidewall 110S1 is configured to gradually reduce a horizontal distance between the wires 610 of the wire bundle structure 31. In some arrangements, the sidewall 110S1 is configured to increase a contact area between the wires 610 of the wire bundle structure 31.

In some arrangements, the lower surface of the wire bundle structure 31 is spaced apart from the bottom surface of the trench 110T1. In some arrangements, lower surfaces of the wires 610 are spaced apart from the bottom surface of the trench 110T1. In some arrangements, the lower surface of the wire bundle structure 32 is partially spaced apart from the bottom surface of the trench 110T2. In some arrangements, lower surfaces of some of the wires 610 are spaced apart from the bottom surface of the trench 110T2.

FIG. 1H is a cross-section of a package structure 1H in accordance with some arrangements of the present disclosure. The structure illustrated in FIG. 1H is similar to that in FIG. 1B, and the differences therebetween are described as follows.

In some arrangements, the sidewalls 110S1 are inclined with respect to the surface 211 of the pad 210. In some arrangements, the sidewall 110S1 is configured to guide the wires 610 of the wire bundle structure 31 to gather toward a direction away from the pad 210. In some arrangements, the sidewall 110S1 is configured to gradually reduce a horizontal distance between the wires 610 of the wire bundle structure 31. In some arrangements, the sidewall 110S1 is configured to increase a contact area between the wires 610 of the wire bundle structure 31.

In some arrangements, the lower surface of the wire bundle structure 31 is spaced apart from the bottom surface of the trench 110T1. In some arrangements, lower surfaces of the wires 610 are spaced apart from the bottom surface of the trench 110T1. In some arrangements, the lower surface of the wire bundle structure 32 is partially spaced apart from the bottom surface of the trench 110T2. In some arrangements, lower surfaces of some of the wires 610 are spaced apart from the bottom surface of the trench 110T2.

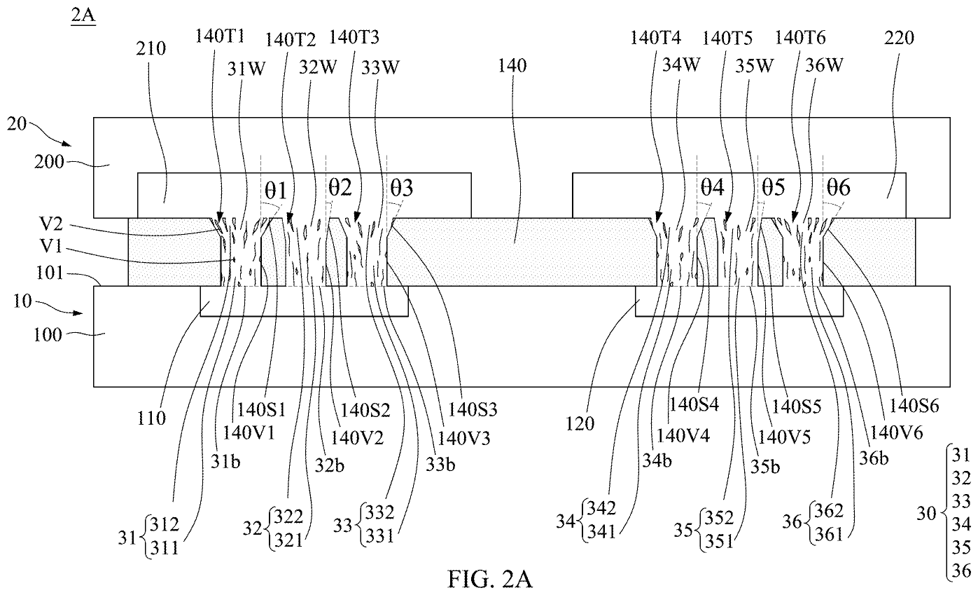

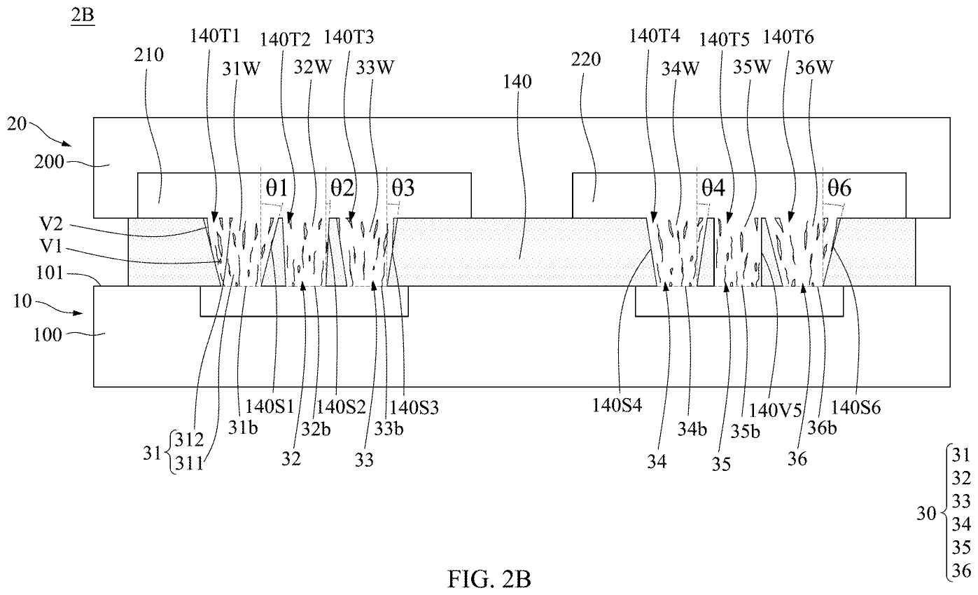

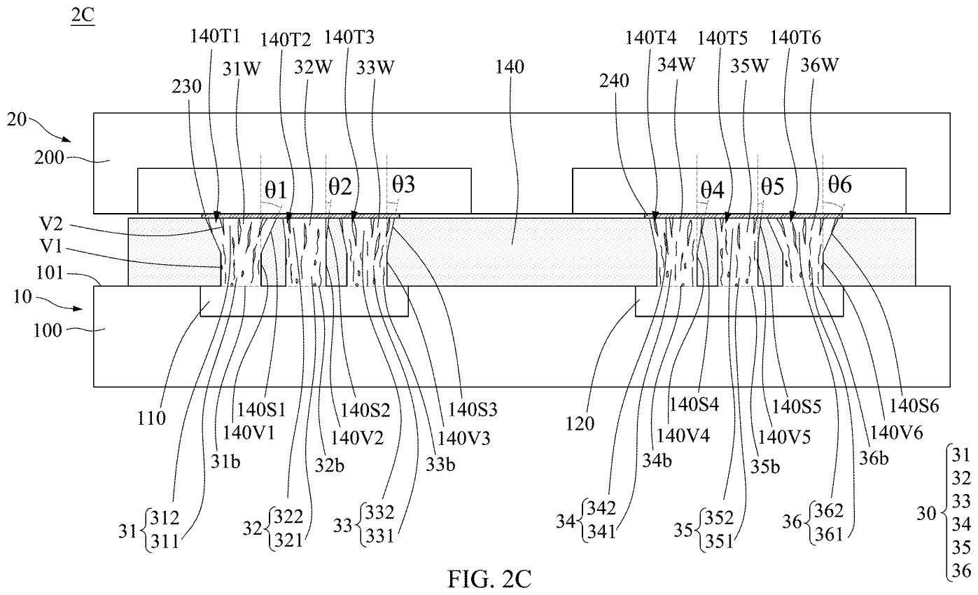

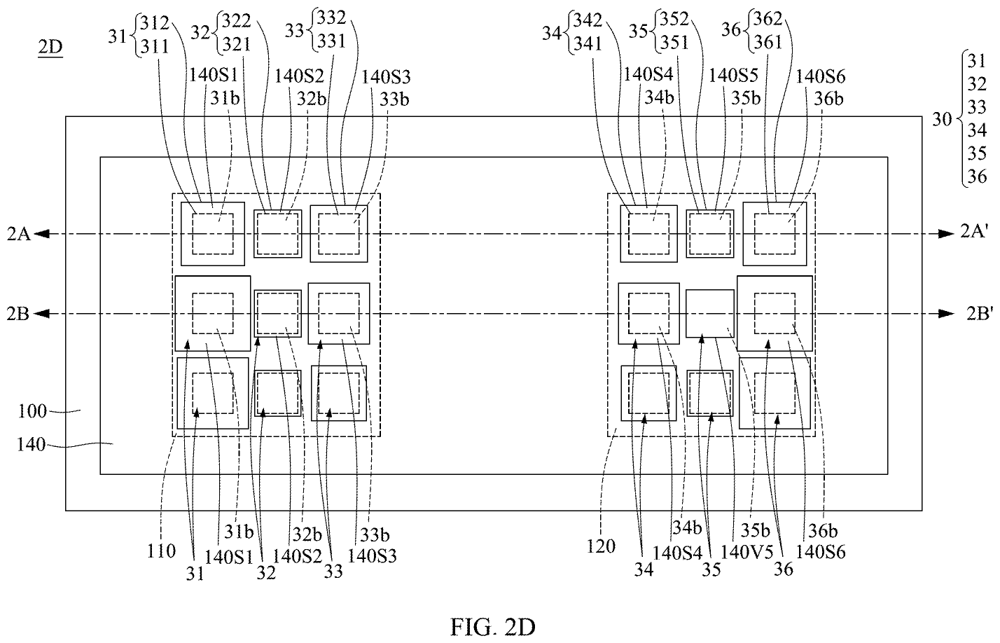

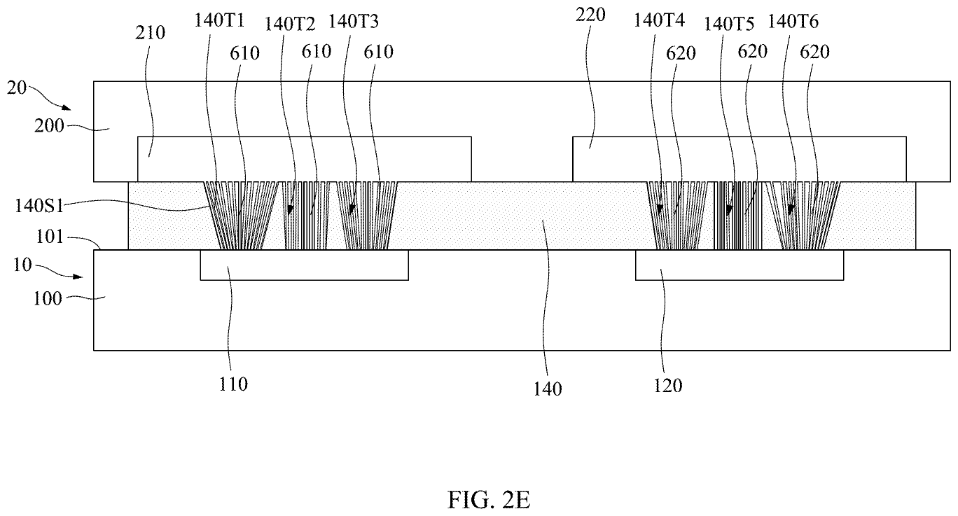

FIG. 2A is a cross-section of a package structure 2A in accordance with some arrangements of the present disclosure. The structure illustrated in FIG. 2A is similar to that in FIG. 1A, and the differences therebetween are described as follows.

In some arrangements, the package structure 2A further includes a dielectric layer 140 over the pad 110. In some arrangements, the pad 110 is spaced apart from the pad 210 by the dielectric layer 140. In some arrangements, the dielectric layer 140 defines one or more trenches (e.g., trenches 140T1, 140T2, 140T3, 140T4, 140T5, and 140T6). The trenches 140T1, 140T2, 140T3, 140T4, 140T5, and 140T6 may be referred to as cavities, through holes, or recesses. In some arrangements, one or more of the trenches 140T1, 140T2, and 140T3 (or the cavities) may at least partially taper toward the base layer 100 or the pad 110. In some arrangements, one or more of the trenches 140T4, 140T5, and 140T6 (or the cavities) may at least partially taper toward the base layer 100 or the pad 120. In some arrangements, one or more of the trenches 140T1, 140T2, 140T3, 140T4, 140T5, and 140T6 (or the cavities) may at least partially taper away from the substrate 20. The dielectric layer 140 may be or include an organic material, a solder mask, polyimide (PI), an ABF, one or more molding compounds, one or more pre-impregnated composite fibers (e.g., a pre-preg material), borophosphosilicate glass (BPSG), silicon oxide, silicon nitride, silicon oxynitride, undoped silicate glass (USG), any combination thereof, or the like. In some arrangements, the dielectric layer 140 is formed of or includes PI.

In some arrangements, each of the trenches 140T1, 140T2, 140T3, 140T4, 140T5, and 140T6 has one or more inclined sidewalls inclined with respect to the base layer 100. In some arrangements, each of the trenches 140T1, 140T2, 140T3, 140T4, 140T5, and 140T6 further has one or more vertical sidewalls extending toward the base layer 100, and the one or more inclined sidewalls are inclined with respect to the corresponding vertical sidewalls. In some arrangements, the trench 140T1 has a vertical sidewall 140V1 and a sidewall 140S1 inclined with respect to the vertical sidewall 140V1. In some arrangements, the trench 140T2 has a vertical sidewall 140V2 and a sidewall 140S2 inclined with respect to the vertical sidewall 140V2. In some arrangements, the trench 140T3 has a vertical sidewall 140V3 and a sidewall 140S3 inclined with respect to the vertical sidewall 140V3. In some arrangements, the trench 140T4 has a vertical sidewall 140V4 and a sidewall 140S4 inclined with respect to the vertical sidewall 140V4. In some arrangements, the trench 140T5 has a vertical sidewall 140V5 and a sidewall 140S5 inclined with respect to the vertical sidewall 140V5. In some arrangements, the trench 140T6 has a vertical sidewall 140V6 and a sidewall 140S6 inclined with respect to the vertical sidewall 140V6. In some arrangements, at least two slopes of at least two sidewalls of the trenches 140T1, 140T2, 140T3, 140T4, 140T5, and 140T6 are different from each other. For example, a slope of the sidewall 140S1 of the trench 140T1 is different from a slope of the sidewall 140S2 of the trench 140T2. For example, a slope of the sidewall 140S4 of the trench 140T4 is different from a slope of the sidewall 140S5 of the trench 140T5.

In some arrangements, the trench 140T1 accommodates the wire bundle structure 31. In some arrangements, a cross-sectional profile of the wire bundle structure 31 is substantially conformal with a cross-sectional shape of the trench 140T1. In some arrangements, the portion 311 of the wire bundle structure 31 directly contacts the sidewall 140V1 of the trench 140T1 of the dielectric layer 140. In some arrangements, the wire bundle structure 31 (or the portion 311) is partially spaced apart from the sidewall 140V1 of the trench 140T1 by at least one of the voids V1 in the portion 311 of the wire bundle structure 31. In some arrangements, the wire bundle structure 31 (or the portion 312) is partially spaced apart from the sidewall 140S1 of the trench 140T1 by at least one of the voids V2 in the portion 312 of the wire bundle structure 31.

In some arrangements, the wire bundle structures 32, 33, 34, and 36 include tapered structures similar to that of the wire bundle structure 31. In some arrangements, two or more sidewalls (e.g. the sidewalls 140S1, 140S2, 140S3, 140S4, and 140S6) of the wire bundle structures 31, 32, 33, 34, and 36 may have different inclined angles (e.g., angles θ1, θ2, θ3, θ4, and θ6). In some arrangements, the angle θ1 is greater than the angle θ3. In some arrangements, the angle θ3 is greater than the angle θ2. In some arrangements, the angle θ6 is greater than the angle θ5.

In some arrangements, the dielectric layer 140 may be referred to as a guiding structure. The guiding structure (e.g., the dielectric layer 140) may define a plurality of trenches tapering toward the base layer 100. The trenches of the guiding structure (e.g., the dielectric layer 140) may taper away from the substrate 20. In some arrangements, the pad 110 is exposed by the trenches 140T1, 140T2, and 140T3 (or the through holes) of the guiding structure (e.g., the dielectric layer 140) and contacting the wires 31W, 32W, and 33W. In some arrangements, the pad 120 is exposed by the trenches 140T4, 140T5, and 140T6 (or the through holes) of the guiding structure (e.g., the dielectric layer 140) and contacting the wires 34W, 35W, and 36W. In some arrangements, the guiding structure (or the dielectric layer 140) is configured to reduce entanglement of the wires 31W, 32W, 33W, 34W, 35W, and 36W.

In some arrangements, the guiding structure (or the dielectric layer 140) defines a plurality of guiding slopes (or slopes) configured for directing the wires to extend from the substrate 20 toward the substrate 10 along the guiding slopes. For example, the sidewall 140S1 defined by the dielectric layer 140 may serve as a guiding slope that is configured for directing the wires 31W to extend from the pad 210 of the substrate 20 toward the substrate 10 along the sidewall 140S1. In some arrangements, an angle θ1 defined by the slope or the guiding slope (e.g., the sidewall 140S1) and a normal line of a surface 101 of the substrate 10 is from about 15° to about 45°. In some arrangements, the plurality of guiding slopes may include a first slope (e.g., the sidewall 140S1) adjacent to an edge of the guiding structure and a second slope (e.g., the sidewall 140S2) distal from the edge of the guiding structure. In some arrangements, an angle θ2 defined by the second slope (e.g., the sidewall 140S2) and the normal line of the surface 101 of the substrate 10 may be substantially the same as or different from the angle θ1. In some arrangements, the angle θ1 is from about 15° to about 45° and greater than the angle θ2, such that the wires 31W may be directed to extend downward to the surface 101 of the substrate 10 without bending outwards and protruding the edge of the dielectric layer 140.

In some arrangements, the guiding structure (or the dielectric layer 140) further defines a plurality of vertical sidewalls each connected to each of the guiding slopes and configured for further directing the wires to extend toward the substrate 10 along the vertical sidewalls. For example, the vertical sidewall 140V1 is connected to the sidewall 140S1 and configured for further directing the wires 31W to extend toward the substrate 10 along the vertical sidewall 140V1. In some arrangements, at least two vertical sidewalls of the plurality of vertical sidewalls have different heights. For example, the vertical sidewalls 140V1 and 140V2 have different heights. For example, the vertical sidewalls 140V4 and 140V5 have different heights.

In some arrangements, the guiding structure (or the dielectric layer 140) includes trenches having tapered structures or tapered cross-sectional profiles that are defined by the guiding slopes and the vertical sidewalls. For example, the tapered structure of the trench 140T1 is defined by the sidewall 140S1 and the vertical sidewall 140V1. In some arrangements, the wires 31W are disposed in the trench 140T1, and a spacing between the wires 31W decreases toward the substrate 10. In some arrangements, the wires 32W are disposed in the trench 140T2, and a spacing between the wires 32W decreases toward the substrate 10. In some arrangements, the wires 33W are disposed in the trench 140T3, and a spacing between the wires 33W decreases toward the substrate 10. In some arrangements, the wires 34W are disposed in the trench 140T4, and a spacing between the wires 34W decreases toward the substrate 10. In some arrangements, the wires 35W are disposed in the trench 140T5, and a spacing between the wires 35W decreases toward the substrate 10. In some arrangements, the wires 36W are disposed in the trench 140T6, and a spacing between the wires 36W decreases toward the substrate 10. For example, some portions of the wires 31W (e.g., upper portions of the wires 31W in the portion 312) may be partially spaced apart from each other by the relatively large voids V2, such that the spacing between the wires 31W in the portion 312 may be relatively large. In addition, for example, some portions of the wires 31W (e.g., lower portions of the wires 31W in the portion 311) may be forced or pushed to be close to each other by the narrow lower portion of the trench 140T1 and thus are partially spaced apart from each other by the relatively small voids V1, such that the spacing between the wires 31W in the portion 311 may be relatively small. Similar situation may be applied to the wires 32W, 33W, 34W, 35W, and 36W.

In some arrangements, the pad 110, the pad 210, the dielectric layer 140, and the wire bundle structure 31 may collectively form a bonding structure for bonding the substrate 10 to the substrate 20. In some arrangements, the pad 110, the pad 210, the dielectric layer 140, and the wire bundle structures 31, 32, and 33 may collectively form a bonding structure for bonding the substrate 10 to the substrate 20. In some arrangements, the pad 120, the pad 220, the dielectric layer 140, and the wire bundle structures 34, 35, and 36 may collectively form a bonding structure for bonding the substrate 10 to the substrate 20. In some arrangements, the pads 110 and 120, the pads 210 and 220, the dielectric layer 140, and the wire bundle structures 31, 32, 33, 34, 35, and 36 may collectively form a bonding structure for bonding the substrate 10 to the substrate 20.

FIG. 2B is a cross-section of a package structure 2B in accordance with some arrangements of the present disclosure. The structure illustrated in FIG. 2B is similar to that in FIG. 2A, and the differences therebetween are described as follows.

In some arrangements, one or more of the lower portions of the wire bundle structures may further taper away from the upper portions of the wire bundle structures. For example, the portion 311 tapers away from the portion 312. In some arrangements, the portion 311 is or includes a tapered portion and has a width decreasing away from the portion 312. In some arrangements, the portions 311 and 312 collectively form a tapered structure tapering from the pad 210 toward the surface 101 of the substrate 10. In some arrangements, the wire bundle structure 31 includes a tapered structure having a sidewall (e.g., the sidewall 140S1) extending between the pad 210 and the pad 110.

In some arrangements, the wire bundle structures 32, 33, 34, and 36 include tapered structures similar to that of the wire bundle structure 31. In some arrangements, two or more sidewalls (e.g. the sidewalls 140S1, 140S2, 140S3, 140S4, and 140S6) of the wire bundle structures 31, 32, 33, 34, and 36 may have different inclined angles (e.g., angles θ1, θ2, θ3, θ4, and θ6). In some arrangements, the angle θ1 is greater than the angle θ3. In some arrangements, the angle θ3 is greater than the angle θ2. In some arrangements, the angle θ6 is greater than the angle θ5.

In some arrangements, the wire bundle structure 35 includes a columnar structure having a substantially vertical sidewall (e.g. the vertical sidewall 140V5).

FIG. 2C is a cross-section of a package structure 2C in accordance with some arrangements of the present disclosure. The structure illustrated in FIG. 2C is similar to that in FIG. 2A, and the differences therebetween are described as follows.

In some arrangements, the package structure 2C further includes one or more seed layers (e.g., seed layers 230 and 240). In some arrangements, the seed layer 230 is between the pad 210 and the wire bundle structures 31 32, and 33. In some arrangements, the seed layer 230 directly contacts the pad 210. In some arrangements, the seed layer 230 directly contacts the wire bundle structures 31 32, and 33. In some arrangements, the seed layer 240 is between the pad 220 and the wire bundle structures 34 35, and 36. In some arrangements, the seed layer 240 directly contacts the pad 220. In some arrangements, the seed layer 240 directly contacts the wire bundle structures 34 35, and 36.

In some arrangements, a portion of the seed layer 230 is exposed to at least one void V2 in the upper portion (e.g., the portions 312, 322, and 332) of the wire bundle structure (e.g., the wire bundle structures 31, 32, and 33). In some arrangements, a portion of the sidewall (e.g., the sidewalls 140S1, 140S2, and 140S3) of the trench (e.g., the trenches 140T1, 140T2, and 140T3) is further exposed to at least one void V2 in the upper portion (e.g., the portions 312, 322, and 332) of the wire bundle structure (e.g., the wire bundle structures 31, 32, and 33). In some arrangements, a portion of the seed layer 240 is exposed to at least one void V2 in the upper portion (e.g., the portions 342, 352, and 362) of the wire bundle structure (e.g., the wire bundle structures 34, 35, and 36). In some arrangements, In some arrangements, a portion of the sidewall (e.g., the sidewalls 140S1, 140S2, and 140S3) of the trench (e.g., the trenches 140T1, 140T2, and 140T3) is further exposed to at least one void V2 in the upper portion (e.g., the portions 342, 352, and 362) of the wire bundle structure (e.g., the wire bundle structures 34, 35, and 36).

FIG. 2D is a top view of a package structure 2D in accordance with some arrangements of the present disclosure. In some arrangements, FIG. 2D shows a top view of a portion of the package structure 2A illustrated in FIG. 2A. In some arrangements, FIG. 2A shows a cross-section along a line 2A-2A′ in FIG. 2D. In some arrangements, FIG. 2D shows a top view of a portion of the package structure 2B illustrated in FIG. 2B. In some arrangements, FIG. 2B shows a cross-section along a line 2B-2B′ in FIG. 2D. In some arrangements, FIG. 2D shows a top view of a portion of the package structure 2C illustrated in FIG. 2C. It should be noted that some elements (e.g., the substrate 20 and the pads 210 and 220) are omitted in FIG. 2D for clarity.

In some arrangements, a plurality of wire bundle structures (e.g., the wire bundle structure 31, 32, and 33) are connected to the pad 110, and a plurality of wire bundle structures (e.g., the wire bundle structure 34, 35, and 36) are connected to the pad 120.

In some arrangements, referring to FIG. 2A and FIG. 2D, the inclined angles (e.g., the angles θ1 and θ3) of the guiding slopes of the guiding structure over the edge portion of the pad 110 are greater than the inclined angle (e.g., the angle θ2) of the guiding slope of the guiding structure over the middle portion of the pad 110. In some arrangements, referring to FIG. 2A and FIG. 2D, the inclined angles (e.g., the angles θ4 and θ6) of the guiding slopes of the guiding structure over the edge portion of the pad 120 are greater than the inclined angle (e.g., the angle θ5) of the guiding slope of the guiding structure over the middle portion of the pad 120. In some arrangements, referring to FIG. 2B and FIG. 2D, the inclined angles (e.g., the angles θ1 and θ3) of the guiding slopes of the guiding structure over the edge portion of the pad 110 are greater than the inclined angle (e.g., the angle θ2) of the guiding slope of the guiding structure over the middle portion of the pad 110. In some arrangements, areas of bottom surfaces of the vertical portions of the wire bundle structures are substantially the same. In some arrangements, an area of the top surface of the tapered portion of the wire bundle structure (e.g., the wire bundle structures 31, 33, 34, and 36) over the edge portion of the pad 110 and/or the pad 120 is greater than an area of the top surface of the tapered portion of the wire bundle structures (e.g., the wire bundle structures 32 and 35) over the middle portion of the pad 110 and/or the pad 120.

According to some arrangements of the present disclosure, the inclined angles of the guiding slopes of the guiding structure in the edge portion of the pad are greater than the inclined angle of the guiding slope of the guiding structure in the middle portion of the pad. Since the wires in the middle portion of the pad are less likely to protrude outwards the edges of the pad, the wires may only extend between edges of the trenches. Therefore, with the inclined angles of the guiding slopes of the guiding structure in the middle portion of the pad being reduced, the area of the top surface of the tapered portion of the trench of the guiding structure in the middle portion of the pad can be reduced (e.g., the areas of the top surfaces of the tapered portions of the wire bundle structures 32 and 35), and thus the overall area or size of the package structure can be reduced.

FIG. 2E is a cross-section of a package structure 2E in accordance with some arrangements of the present disclosure. The structure illustrated in FIG. 2E is similar to that in FIG. 2A, and the differences therebetween are described as follows.

In some arrangements, the sidewalls 140S1 are inclined with respect to the surface 211 of the pad 210. In some arrangements, the sidewall 140S1 is configured to guide the wires 610 of the wire bundle structure 31 to gather toward a direction away from the pad 210. In some arrangements, the sidewall 140S1 is configured to gradually reduce a horizontal distance between the wires 610 of the wire bundle structure 31. In some arrangements, the sidewall 140S1 is configured to increase a contact area between the wires 610 of the wire bundle structure 31.

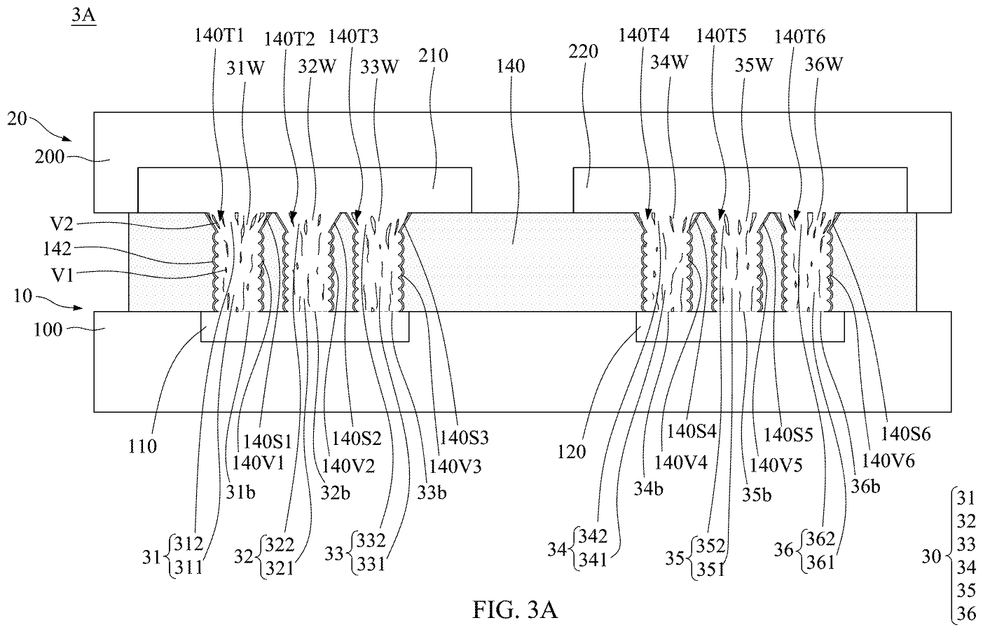

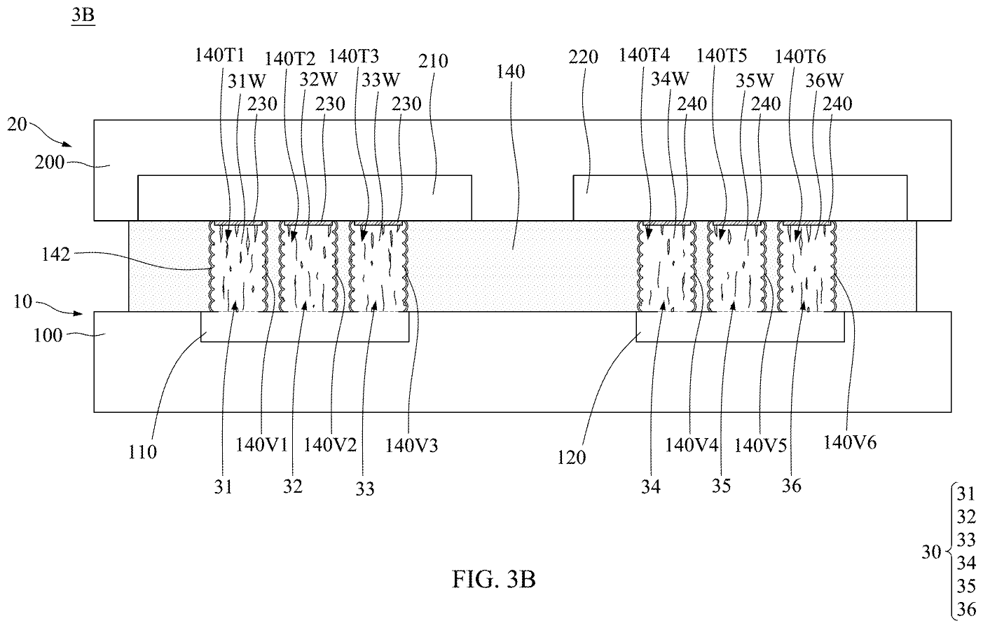

FIG. 3A is a cross-section of a package structure 3A in accordance with some arrangements of the present disclosure. The structure illustrated in FIG. 3A is similar to that in FIG. 2A, and the differences therebetween are described as follows.

In some arrangements, one or more of the vertical sidewalls (e.g., the sidewalls 140V1, 140V2, 140V3, 140V4, 140V5, and 140V6) may include a plurality of curved surfaces. In some arrangements, one or more of the vertical sidewalls (e.g., the sidewalls 140V1, 140V2, 140V3, 140V4, 140V5, and 140V6) may include a plurality of concave surfaces (also referred to as “recesses”). The concave surface may be concave toward the dielectric layer 140.

In some arrangements, the package structure 3A further includes a protective layer 142 on the vertical sidewalls (e.g., the sidewalls 140V1, 140V2, 140V3, 140V4, 140V5, and 140V6). In some arrangements, the protective layer 142 is further formed or disposed on the inclined sidewalls (e.g., the sidewalls 140S1, 140S2, 140S3, 140S4, 140S5, and 140S6). In some arrangements, the wire bundle structures 31, 32, 33, 34, 35, and 36 are covered or encapsulated by the protective layer 142.

FIG. 3B is a cross-section of a package structure 3B in accordance with some arrangements of the present disclosure. The structure illustrated in FIG. 3B is similar to that in FIG. 3A, and the differences therebetween are described as follows.

In some arrangements, the guiding structure (or the dielectric layer 140) defines a plurality of sidewalls (e.g., the sidewalls 140V1, 140V2, 140V3, 140V4, 140V5, and 140V6) configured for directing the wires to extend from the substrate 20 toward the substrate 10, and each of the sidewalls includes a plurality of concave surfaces (also referred to as “recesses”). The concave surface may be concave toward the dielectric layer 140.

In some arrangements, the dielectric layer 140 of the structures illustrated in FIG. 3A and/or FIG. 3B may be replaced by a semiconductor layer (e.g., a silicon-based layer), and wire bundle structures 31, 32, 33, 34, 35, and 36 may be referred to as conductive through vias (e.g., through silicon vias; TSVs). In some arrangements, a structure including a semiconductor layer replacing the dielectric layer 140 with the wire bundle structures 31, 32, 33, 34, 35, and 36 penetrating the semiconductor layer may be referred to as an interposer.

According to some arrangements of the present disclosure, the sidewalls having a plurality of recesses or concave surfaces, the adhesion between the wires and the sidewalls can be increased, and thus the structural strength and the reliability of the can be increased.

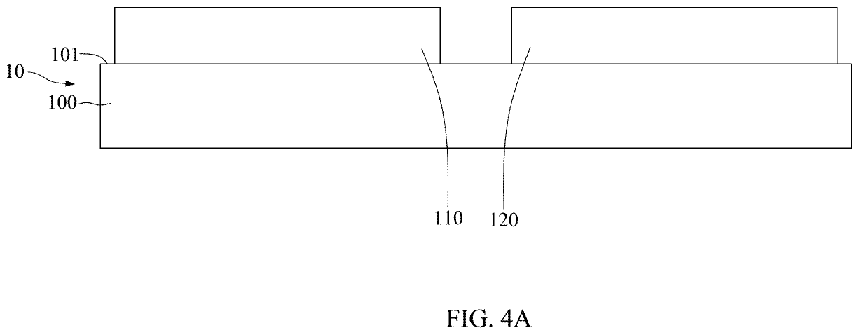

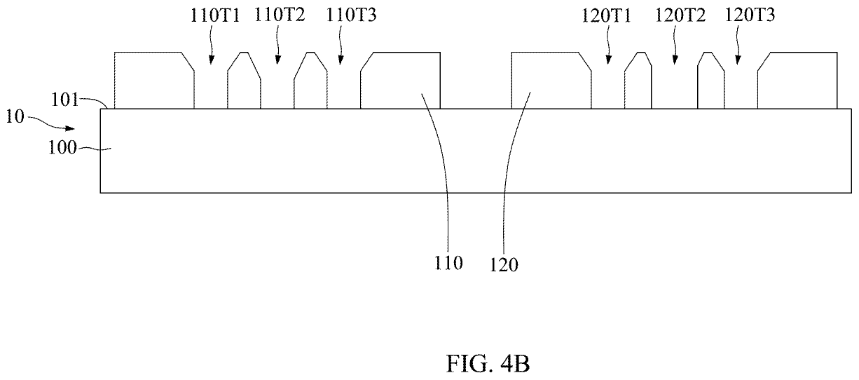

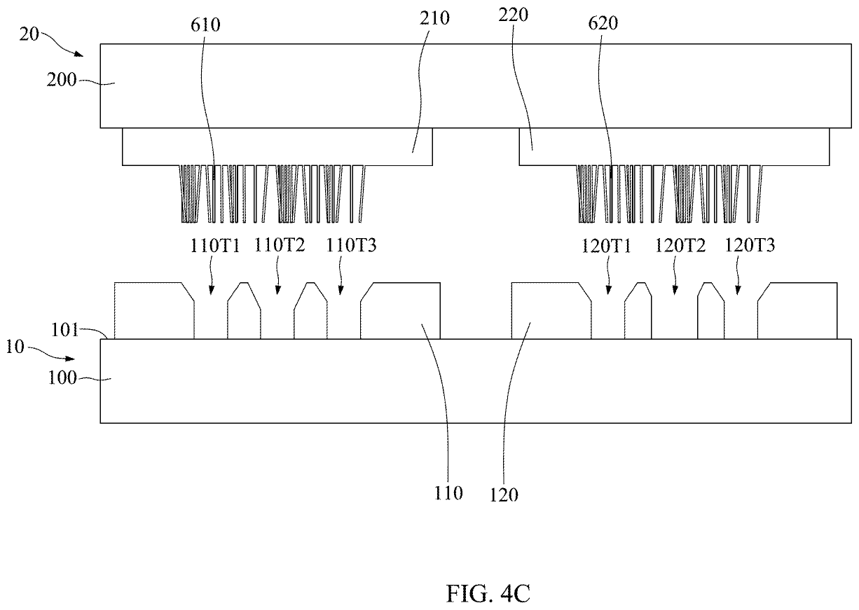

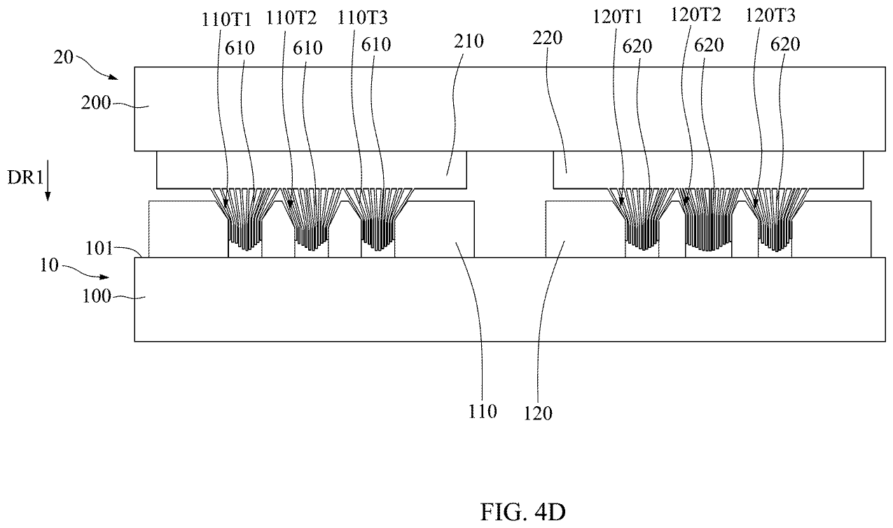

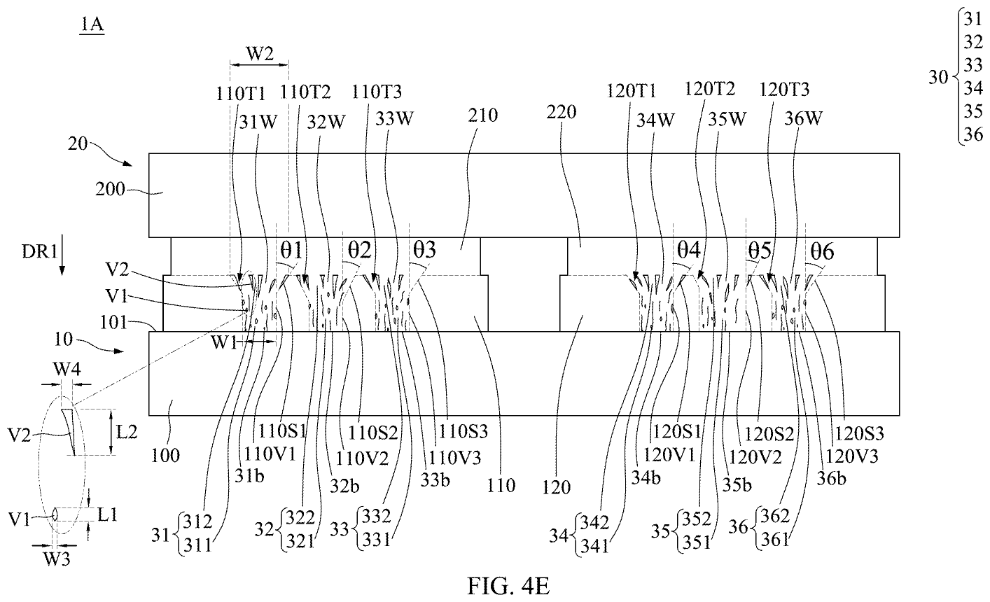

FIG. 4A, FIG. 4B, FIG. 4C, FIG. 4D, and FIG. 4E illustrate various stages of an exemplary method for manufacturing a package structure 1A in accordance with some embodiments of the present disclosure.

Referring to FIG. 4A, a substrate 10 may be provided. The substrate 10 may include a base layer 100 and pads 110 and 120.

Referring to FIG. 4B, trenches 110T1, 110T2, and 110T3 may be formed in the pad 110, and trenches 120T1, 120T2, and 120T3 may be formed in the pad 120. The trenches may be formed by etching or laser drilling technique.

Referring to FIG. 4C, a substrate 20 including a base layer 200 and pads 210 and 220 may be provided, and wires 610 and 620 may be formed on the pads 210 and 220, respectively. The wires 610 and 620 may be or include conductive wires, e.g., conductive nanowires.

Referring to FIG. 4D, the wires 610 may be guided or directed to be disposed in the trenches 110T1, 110T2, and 110T3, and the wires 620 may be guided or directed to be disposed in the trenches 120T1, 120T2, and 120T3. In some arrangements, the wires 610 are directed to extend along the sidewalls 110S1, 110S2, and 110S3 (or the guiding slopes) toward inside the 110T1, 110T2, and 110T3. In some arrangements, the wires 620 are directed to extend along the sidewalls 120S1, 120S2, and 120S3 (or the guiding slopes) toward inside the trenches 120T1, 120T2, and 120T3. In some arrangements, a spacing between portions of the wires 610 and 620 in upper portions of the trenches (e.g., portions defined by the inclined sidewalls) is larger than a spacing between the portions of the wires 610 and 620 in lower portions of the trenches (e.g., portions defined by the vertical sidewalls). In some arrangements, the portions of the wires 610 and 620 in lower portions of the trenches are forced or pushed to be close to each other by the relatively narrow lower portions of the trenches. In some arrangements, the portions of the wires 610 and 620 in upper portions of the trenches are relatively loosely arranged with each other due to the relatively wide upper portions of the trenches.

Referring to FIG. 4E, a thermal operation may be performed to sinter the wires 610 and 620 to form a bundle structure 30 including wire bundle structures 31, 32, 33, 34, 35, and 36 that connect the pads 210 and 220 to the pads 110 and 120. In some arrangements, the portions of the wires 610 and 620 that are relatively closely arranged with other in lower portions of the trenches are sintered to form the portions 311, 321, 331, 341, 351, and 361 having smaller and less voids V1. In some arrangements, the portions of the wires 610 and 620 that are relatively loosely arranged with other in upper portions of the trenches are sintered to form the portions 312, 322, 332, 342, 352, and 362 having larger and more voids V2. As such, the package structure 1A including the substrates 10 and 20 and the bundle structure 30 as illustrated in FIG. 1A may be formed.

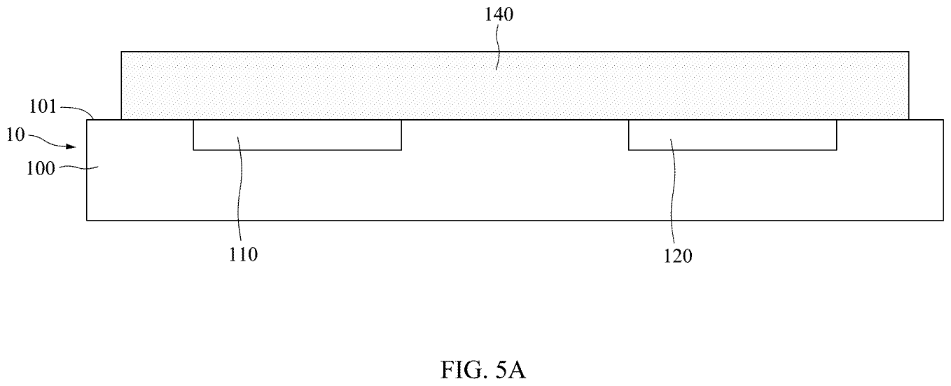

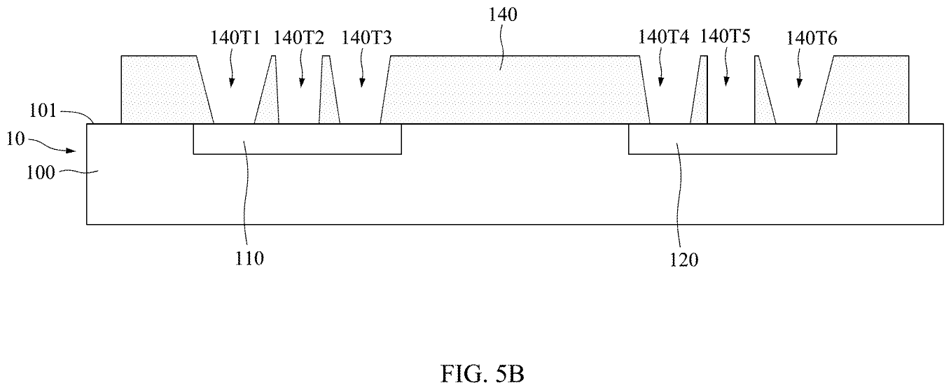

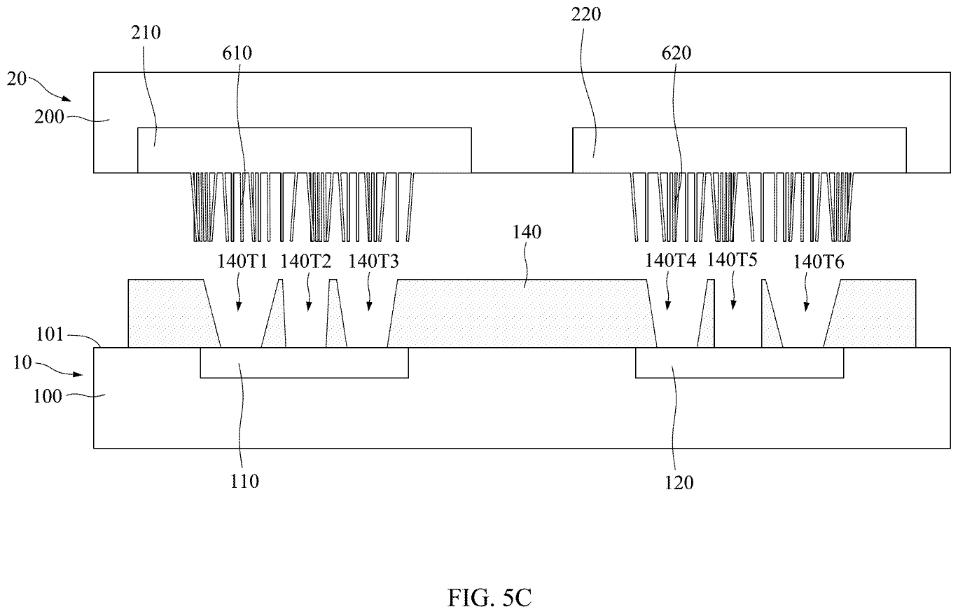

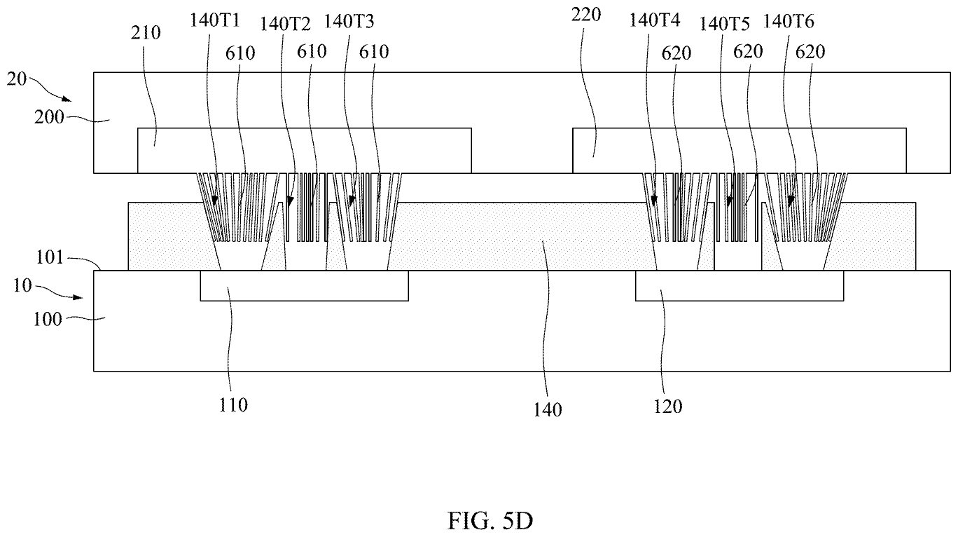

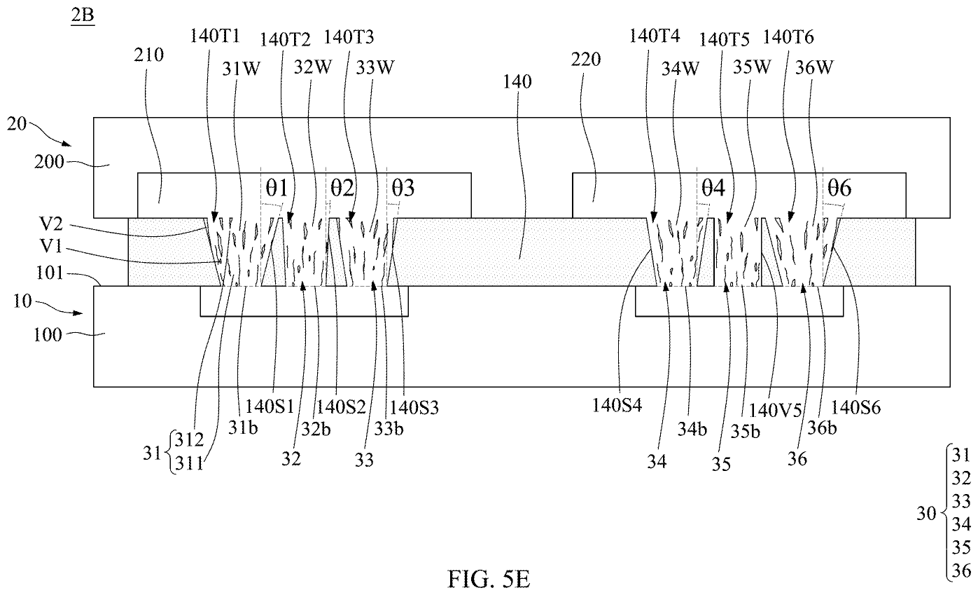

FIG. 5A, FIG. 5B, FIG. 5C, FIG. 5D, and FIG. 5E illustrate various stages of an exemplary method for manufacturing a package structure 2B in accordance with some embodiments of the present disclosure.

Referring to FIG. 5A, a substrate 10 may be provided. The substrate 10 may include a base layer 100, pads 110 and 120, and a dielectric layer 140.

Referring to FIG. 5B, trenches 140T1, 140T2, 140T3, 140T4, 140T5, and 140T6 may be formed in the dielectric layer 140. The trenches may be formed by etching or laser drilling technique.

Referring to FIG. 5C, a substrate 20 including a base layer 200 and pads 210 and 220 may be provided, and wires 610 and 620 may be formed on the pads 210 and 220, respectively. The wires 610 and 620 may be or include conductive wires, e.g., conductive nanowires.

Referring to FIG. 5D, the wires 610 may be guided or directed to be disposed in the trenches 140T1, 140T2, and 140T3, and the wires 620 may be guided or directed to be disposed in the trenches 140T4, 140T5, and 140T6. In some arrangements, the wires 610 are directed to extend along the sidewalls 140S1, 140S2, and 140S3 (or the guiding slopes) toward inside the 140T1, 140T2, and 140T3 to contact the pad 110. In some arrangements, the wires 620 are directed to extend along the sidewalls 140S4, 140S5, and 140S6 (or the guiding slopes) toward inside the trenches 140T4, 140T5, and 140T6 to contact the pad 120. In some arrangements, a spacing between portions of the wires 610 and 620 in upper portions of the trenches (e.g., portions defined by the inclined sidewalls) is larger than a spacing between the portions of the wires 610 and 620 in lower portions of the trenches (e.g., portions defined by the vertical sidewalls). In some arrangements, the portions of the wires 610 and 620 in lower portions of the trenches are forced or pushed to be close to each other by the relatively narrow lower portions of the trenches. In some arrangements, the portions of the wires 610 and 620 in upper portions of the trenches are relatively loosely arranged with each other due to the relatively wide upper portions of the trenches.

Referring to FIG. 5E, a thermal operation may be performed to sinter the wires 610 and 620 to form a bundle structure 30 including wire bundle structures 31, 32, 33, 34, 35, and 36 that connect the pads 210 and 220 to the pads 110 and 120. In some arrangements, the portions of the wires 610 and 620 that are relatively closely arranged with other in lower portions of the trenches are sintered to form the portions 311, 321, 331, 341, 351, and 361 having smaller and less voids V1. In some arrangements, the portions of the wires 610 and 620 that are relatively loosely arranged with other in upper portions of the trenches are sintered to form the portions 312, 322, 332, 342, 352, and 362 having larger and more voids V2. As such, the package structure 2B including the substrates 10 and 20 and the bundle structure 30 as illustrated in FIG. 2B may be formed.

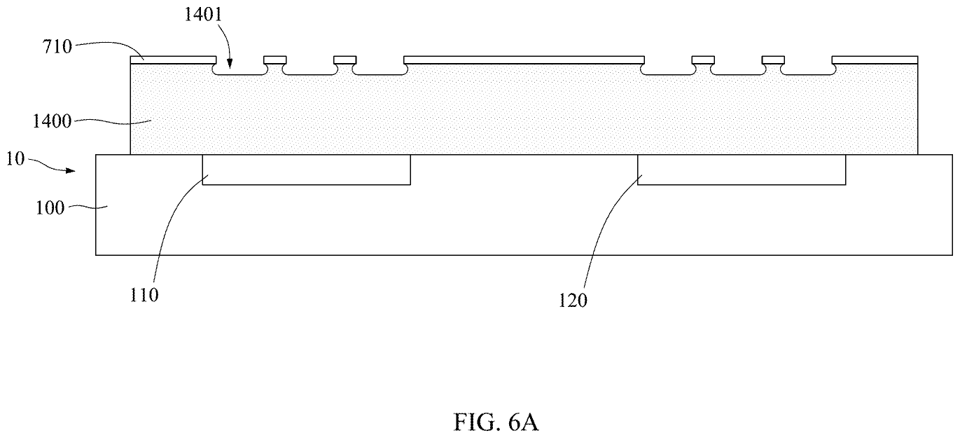

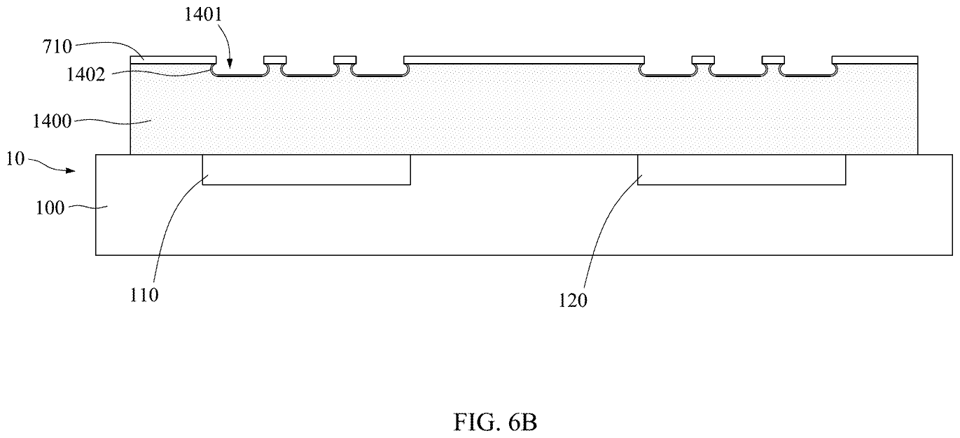

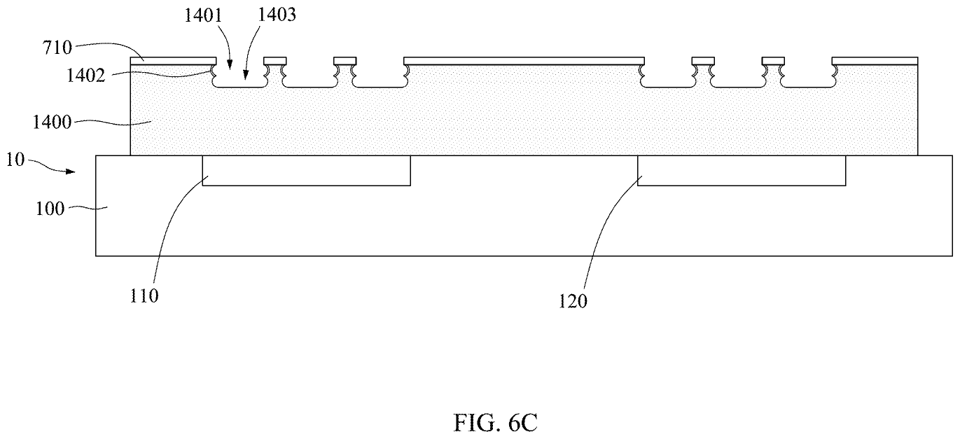

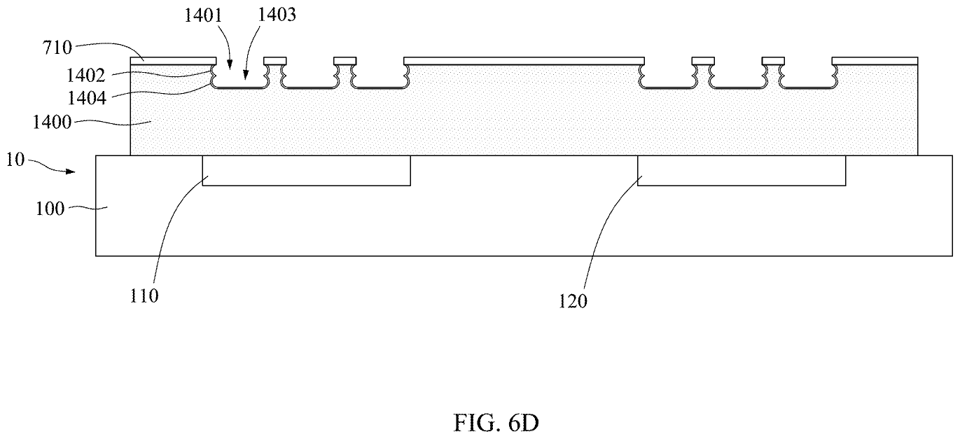

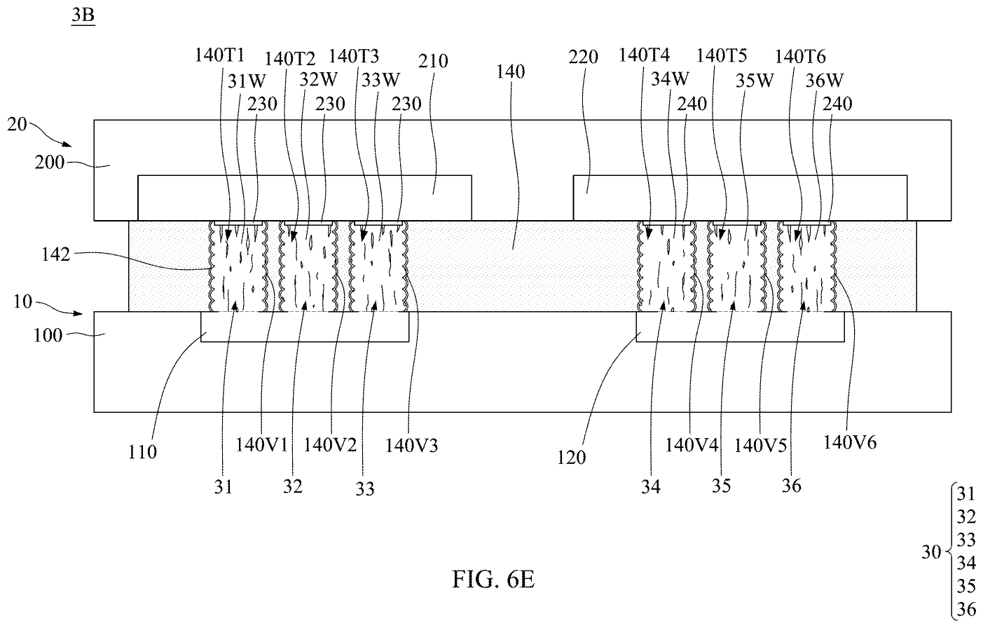

FIG. 6A, FIG. 6B, FIG. 6C, FIG. 6D, and FIG. 6E illustrate various stages of an exemplary method for manufacturing a package structure 3B in accordance with some embodiments of the present disclosure.

Referring to FIG. 6A, a substrate 10 including a base layer 100 and pads 110 and 120 may be provided, a dielectric layer 1400 may be formed or disposed on the substrate 10, and cavities 1401 may be formed in the dielectric layer 1400, and

In some arrangements, a patterned mask layer 710 may be formed over the dielectric layer 1400 to expose portions of an upper surface of the dielectric layer 1400, and cavities 1401 may be formed in the dielectric layer 1400 and exposed by the patterned mask layer 710. The cavities 1401 may be formed by an isotropic etching operation. The etching operation may include applying an etchant including SF₆ along with applying plasma.

Referring to FIG. 6B, passivation layers 1402 may be formed on surfaces of the cavities 1401. In some arrangements, a passivation agent may be applied on exposed surfaces of the cavities 1401 to form passivation layers 1402 on the exposed surfaces of the cavities 1401. The operation for forming the passivation layers 1402 may include applying a passivation agent including C₄F₈ along with applying plasma.

Referring to FIG. 6C, operations similar to those illustrated in FIG. 6A may be performed to further form cavities 1403 each connected to each of the cavities 1401.

Referring to FIG. 6D, operations similar to those illustrated in FIG. 6B may be performed to form passivation layers 1404 on surfaces of the cavities 1403.

Referring to FIG. 6E, operations similar to those illustrated in FIG. 6A and FIG. 6B may be repeated until trenches 140T1, 140T2, 140T3, 140T4, 140T5, and 140T6 with sidewalls 140V1, 140V2, 140V3, 140V4, 140V5, and 140V6 each including a plurality of concave surfaces may be formed, the patterned mask layer 710 may be removed, and operations similar to those illustrated in FIG. 4C to FIG. 4E or FIG. 5C to FIG. 5E may be performed to provide a substrate 20 including a base layer 200 and pads 210 and 220, form wires 610 and 620 on the pads 210 and 220, direct the wires 610 and 620 to be disposed in the trenches 140T1, 140T2, 140T3, 140T4, 140T5, and 140T6, and perform a thermal operation to sinter the wires 610 and 620 to form a bundle structure 30 including wire bundle structures 31, 32, 33, 34, 35, and 36 that connect the pads 210 and 220 to the pads 110 and 120. As such, the package structure 3B including the substrates 10 and 20 and the bundle structure 30 as illustrated in FIG. 3B may be formed.

Spatial descriptions, such as “above,” “below,” “up,”, “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1, less than or equal to ±0.5°, less than or equal to ±0.10, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A bonding structure, comprising:
a first pad; and
a wire bundle structure protruded from the first pad and tapering away from the first pad, wherein the wire bundle structure comprises a first portion and a second portion, the first portion is closer to the first pad than the second portion is, and in a cross-sectional view perspective, a width of a first void in the first portion is less than a width of a second void in the second portion.

2. The bonding structure as claimed in claim 1, wherein the first portion has a plurality of the first voids, the second portion has a plurality of the second voids, and a number of the second voids in the second portion is greater than a number of the first voids in the first portion.

3. The bonding structure as claimed in claim 1, wherein in the cross-sectional view perspective, the second void in the second portion has a strip shape.

4. The bonding structure as claimed in claim 3, wherein the width of the second void increases toward the first pad.

5. The bonding structure as claimed in claim 1, further comprising a second pad having a recess for accommodating the wire bundle structure, wherein in the cross-sectional view perspective, the recess has a first lateral sidewall and a second lateral sidewall opposite to the first lateral sidewall, and a distance between the first lateral sidewall and the second lateral sidewall increases toward the first pad.

6. The bonding structure as claimed in claim 5, wherein the first lateral sidewall is inclined with respect to a surface of the first pad facing the second pad, and the first lateral sidewall is configured to guide a plurality of wires of the wire bundle structure to gather toward a direction away from the first pad.

7. The bonding structure as claimed in claim 5, further comprising a dielectric layer over the second pad and defining a trench for accommodating the wire bundle structure, and the first pad is spaced apart from the second pad by the dielectric layer.

8. The bonding structure as claimed in claim 7, wherein a portion of the dielectric layer is exposed to the second void in the second portion of the wire bundle structure.

9. A bonding structure, comprising:
a first pad;
a second pad over the first pad; and
a wire bundle structure connecting the first pad to the second pad and at least partially tapering in a direction from the second pad toward the first pad, wherein the wire bundle structure comprises a first portion connected to the first pad and a second portion connected to the second pad, and an aspect ratio of a void in the second portion is greater than an aspect ratio of a void in the first portion.

10. The bonding structure as claimed in claim 9, wherein the void in the second portion extends in a direction toward the first portion.

11. The bonding structure as claimed in claim 9, wherein a width of the void in the second portion is greater than a width of the void in the first portion.

12. The bonding structure as claimed in claim 9, further comprising a seed layer between the second pad and the wire bundle structure, wherein a portion of the seed layer is exposed to the void in the second portion of the wire bundle structure.

13. The bonding structure as claimed in claim 9, wherein the first pad defines a trench for accommodating the wire bundle structure, and the wire bundle structure has a lower surface concave toward and at least partially spaced apart from a bottom surface of the trench.

14. The bonding structure as claimed in claim 13, wherein the lower surface has a non-planar surface.

15. A package structure, comprising:
a first substrate comprising a guiding structure;
a second substrate over the first substrate; and
a plurality of wires electrically connected to the first substrate and the second substrate and at least partially contacting the guiding structure, wherein the guiding structure is configured to reduce entanglement of the wires.

16. The package structure as claimed in claim 15, wherein the guiding structure defines a first trench tapering away from the second substrate, the plurality of wires comprise a plurality of first wires disposed in the first trench, and a spacing between the first wires decreases toward the first substrate.

17. The package structure as claimed in claim 16, wherein the guiding structure further defines a second trench tapering away from the second substrate, the plurality of wires further comprise a plurality of second wires disposed in the second trench, and a spacing between the second wires decreases toward the first substrate.

18. The package structure as claimed in claim 17, wherein a slope of a sidewall of the first trench is different from a slope of a sidewall of the second trench.

19. The package structure as claimed in claim 15, wherein the guiding structure defines a first slope adjacent to an edge of the guiding structure and a second slope distal from the edge of the guiding structure, and a first angle defined by the first slope and a normal line of a surface of the first substrate is different from a second angle defined by the second slope and the normal line.

20. The package structure as claimed in claim 15, wherein the guiding structure defines a plurality of sidewalls configured for directing the wires to extend from the second substrate toward the first substrate, and each of the sidewalls comprises a plurality of concave surfaces.
